(19) United States
(12) Patent Application Publication
(10) Pub. No.: US 2026/0088083 A1
(43) Pub. Date: Mar. 26, 2026

(54) COMPUTE IN MEMORY (CIM) MODULE

(71) Applicant: SK hynix Inc., Icheon-si (KR)

(72) Inventor: Ji Hun KIM, Icheon-si (KR)

(21) Appl. No.: 19/338,359

(22) Filed: Sep. 24, 2025

(30) Foreign Application Priority Data
Sep. 24, 2024 (KR) 10-2024-0129084

(51) Int. Cl. G11C 13/00; G06F 7/544

(52) U.S. Cl. CPC G11C 13/0028; G06F 7/5443; G11C 13/0026; G11C 13/0038

(57) ABSTRACT

A Compute In Memory (CIM) module includes a transistor array computer including at least one transistor and at least one resistive random access memory (ReRAM) for each unit cell; a buffer; and a weight gradient computer including at least one unit transistor. The weight gradient computer includes: a row digital-to-analog converter (DAC) configured to apply a voltage corresponding to an initial input voltage value (dI/dG=V) used in multiplication and accumulation (MAC) computation to a first electrode of the unit transistor; a column DAC configured to apply a voltage corresponding to a change amount in error (dE/dI) for MAC computation with respect to a current value formed as a result of performing MAC computation to a second electrode of the unit transistor; and an analog-to-digital converter (ADC) configured to output a digital signal corresponding to a current flowing into a third electrode of the unit transistor.

### CROSS-REFERENCE TO RELATED APPLICATION

This patent document claims priority under 35 U.S.C. § 119(a) and the benefits of Korean patent application No. 10-2024-0129084 filed in the Korean Intellectual Property Office on Sep. 24, 2024, the disclosure of which is incorporated herein by reference in its entirety as part of the disclosure of the present application.

### TECHNICAL FIELD

The technology and implementations disclosed in this patent document generally relate to a semiconductor device, and more particularly to a weight gradient computer included in a Compute In Memory (CIM) module.

### BACKGROUND

A computer designed to use a semiconductor device includes a processor for performing information processing and a memory for providing data to the processor for use in such information processing. Program commands (instructions) and data required to operate the computer are loaded into the memory, and data can be processed according to commands (or instructions) of the processor.

The amount of data exchanged between the processor and the memory is limited, such that data processing speed may be limited. When the amount of large-volume data such as images, audio, or video increases, there may occur an unexpected situation in which the speed at which the memory retrieves (or loads) necessary information is unable to keep up with the processor's performance.

In order to overcome the above issues, in-memory computing technologies, for example, Analog Compute in Memory (ACiM), which enables simultaneous operation and storage due to characteristics of nonvolatile memory, or Processing in Memory (PiM), which integrates the processor and the memory to perform data processing and memory access simultaneously, have recently emerged.

### SUMMARY

Various embodiments of the present disclosure relate to technology capable of improving the efficiency of power consumption of a Compute In Memory (CIM) module that is designed to use semiconductor devices.

Various embodiments of the present disclosure relate to technology for a transistor array for use in a weight gradient computer, which increases the efficiency of an area required for a device design and/or the number of transistors used in the transistor array and reduces costs required for such design.

In accordance with an embodiment of the present disclosure, a Compute In Memory (CIM) module may include: a transistor array computer including at least one transistor and at least one resistive random access memory (ReRAM) for each unit cell; a buffer; and a weight gradient computer including at least one unit transistor. The weight gradient computer may include: a row digital-to-analog converter (DAC) configured to apply a voltage corresponding to an initial input voltage value (dI/dG=V) used in multiplication and accumulation (MAC) computation to a first electrode of the unit transistor; a column digital-to-analog converter (DAC) configured to apply a voltage corresponding to a change amount in error (dE/dI) for MAC computation with respect to a current value formed as a result of performing MAC computation to a second electrode of the unit transistor; and an analog-to-digital converter (ADC) configured to output a digital signal corresponding to a current flowing into a third electrode of the unit transistor.

In accordance with another embodiment of the present disclosure, a Compute In Memory (CIM) module may include: a first transistor array computer in which a plurality of unit transistors is arranged; and a second transistor array computer configured to perform multiplication and accumulation (MAC) computation. The first transistor array may include: a first row digital-to-analog converter (DAC) configured to apply a voltage corresponding to a first initial input voltage value used in the MAC computation to drain electrodes of the unit transistors arranged in a first row of the first transistor array; a first column DAC configured to apply a voltage corresponding to a change amount of a first error for the MAC computation with respect to a first current value formed as a result of performing the MAC computation to gate electrodes of the unit transistors arranged in a first column of the first transistor array; and a first analog-to-digital converter (ADC) configured to output a digital signal corresponding to a current flowing into source electrodes of the unit transistors arranged in the first column.

In accordance with another embodiment of the present disclosure, a Compute In Memory (CIM) module may include: a transistor array computer including at least one transistor and at least one resistive random access memory (ReRAM) for each unit cell; a buffer; and a weight gradient computer in which unit transistors are arranged in a plurality of rows and a plurality of columns. The weight gradient computer may include: a plurality of bit-lines configured to transmit a signal corresponding to an initial input voltage value used in multiplication and accumulation (MAC) computation to first electrodes of unit transistors arranged in each row; a plurality of word-lines configured to transmit, to second electrodes of unit transistors arranged in each column, a signal corresponding to a change amount in error for the MAC computation with respect to a current value formed as a result of performing the MAC computation; and a plurality of source lines configured to transmit a signal corresponding to a current flowing into third electrodes of unit transistors arranged in each column.

It is to be understood that both the foregoing general description and the following detailed description of the present disclosure are illustrative and explanatory and are intended to provide further explanation of the present disclosure as claimed.

### BRIEF DESCRIPTION OF THE DRAWINGS

The above and other features and beneficial aspects of the present disclosure will become readily apparent with reference to the following detailed description when considered in conjunction with the accompanying drawings.

FIG. 1 is a block diagram illustrating an example of a Compute In Memory (CIM) module according to some embodiments of the present disclosure.

FIG. 2 is a block diagram illustrating an example structure of a transistor array computer according to some embodiments of the present disclosure.

FIG. 3 is a block diagram illustrating an example structure of a weight gradient computer according to some embodiments of the present disclosure.

FIG. 4 is a block diagram illustrating example operations of devices for calculating a weight gradient according to some embodiments of the present disclosure.

FIG. 5 is a diagram illustrating unit cells of a transistor array computer according to some embodiments of the present disclosure.

FIGS. 6 and 7 are diagrams illustrating examples of unit transistors of a weight gradient computer according to some embodiments of the present disclosure.

FIG. 8A is a diagram illustrating an example of an inference artificial neural network (ANN) model according to some embodiments of the present disclosure.

FIG. 8B is a diagram illustrating an example of a training artificial neural network (ANN) model according to some embodiments of the present disclosure.

### DETAILED DESCRIPTION

This patent document provides implementations and examples of a weight gradient computer included in a Compute In Memory (CIM) module that may be used in configurations to substantially address one or more technical or engineering issues and to mitigate limitations or disadvantages encountered in some other weight gradient computers. Some implementations of the present disclosure relate to technology capable of improving the efficiency of power consumption of a Compute In Memory (CIM) module designed to use semiconductor devices. Some implementations of the present disclosure relate to technology for a transistor array for use in a weight gradient computer, which increases the efficiency of an area required for a device design and/or the number of transistors used in the transistor array and reduces costs required for such design. In recognition of the issues above, the present disclosure may provide a Compute In Memory (CIM) that increases the efficiency of an area and power consumption of the transistor array for use in a weight gradient computer included in the CIM module.

Reference will now be made in detail to the embodiments of the present disclosure, examples of which are illustrated in the accompanying drawings. Wherever possible, the same reference numbers will be used throughout the drawings to refer to the same or like parts. While the present disclosure is susceptible to various modifications and alternative forms, specific embodiments thereof are shown by way of example in the drawings. However, the present disclosure should not be construed as being limited to the embodiments set forth herein.

Hereinafter, various embodiments will be described with reference to the accompanying drawings. However, it should be understood that the present disclosure is not limited to specific embodiments, but includes various modifications, equivalents and/or alternatives of the embodiments. The embodiments of the present disclosure may provide a variety of effects capable of being directly or indirectly recognized through the present disclosure.

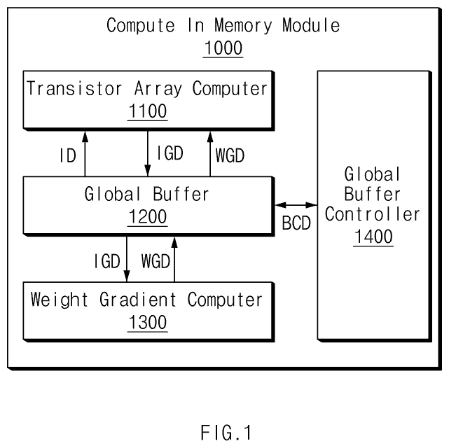

FIG. 1 is a block diagram illustrating an example of a Compute In Memory (CIM) module according to some embodiments of the present disclosure.

Referring to FIG. 1, a CIM module 1000 may be implemented as a part of a computing (calculation) device that performs data processing. The CIM module 1000 may integrate a processor and a memory into one body, so that data stored in the memory can be directly calculated (computed) and processed by the processor in parallel. Therefore, the CIM module 1000 may improve power consumption efficiency and data processing speed. For example, since the CIM module 1000 integrates the memory and the processor into one module, the CIM module 1000 may reduce the consumption of space, power, and/or time required for data communication between the memory and the processor.

In particular, the CIM module 1000 may be used for a machine learning or deep learning algorithm. A machine learning or deep learning algorithm may require a large amount of reference data, and may require multiplication and accumulation (MAC) computation for the reference data. For example, machine learning and/or deep learning algorithms may require multiplication and accumulation (MAC) computation that corresponds to an operation of multiplying gradient data or vectors by a large number of reference data and summing the resultant values.

According to one embodiment, given the large amount of reference data that is a target of MAC computation, the machine learning or deep learning algorithm may utilize the CIM module 1000 to simultaneously access the memory, perform data operations of the processor, and store data in the memory to improve the efficiency of computations such as multiplication or addition. For example, in the CIM module 1000, since the memory and the processor are integrated, consumption of space, power, and/or time required when a large amount of reference data is transferred from the memory to the processor may be reduced.

According to one embodiment, the CIM module 1000 may include a transistor array computer 1100, a global buffer 1200, a weight gradient computer 1300, and/or a global buffer controller 1400. In one example, the CIM module 1000 may integrate one or more data processing devices (e.g., a transistor array computer 1100 or a weight gradient computer 1300) and a data storage (e.g., a global buffer 1200) into one module. In one example, the data processing devices, such as the transistor array computer 1100 or the weight gradient computer 1300 of the CIM module 1000, may quickly perform calculations (or computations), such as addition or multiplication, in parallel.

According to one embodiment, the transistor array computer 1100 may receive input data (ID) from the global buffer 1200. In one example, the transistor array computer 1100 may output input gradient data (IGD) based on the input data (ID).

According to one embodiment, the input data (ID) that is transferred from the global buffer 1200 to the transistor array computer 1100 may include reference data on which MAC computation is performed. For example, the input data (ID) may include image, audio, video data, and/or target data requiring inference.

According to one embodiment, the input gradient data (IGD) that is transferred from the transistor array computer 1100 to the global buffer 1200 may correspond to data generated by the transistor array computer 1100 having processed the input data (ID). In one example, the input gradient data (IGD) may include input data and/or output data of MAC computation performed on an image, audio, video data, and/or target data requiring inference. In one example, the input gradient data (IGD) may include data corresponding to an initial input voltage value and a threshold voltage value that are used in MAC computation and/or a current value formed as a result of performing the MAC computation.

In one embodiment, the initial input voltage value used in MAC computation may correspond to the image, audio, image data, and/or target data requiring inference. In one example, the threshold voltage value used in MAC computation may correspond to a minimum voltage value that must be applied to a gate electrode of a transistor in order for a current to be formed in the transistor performing the MAC computation. In one example, the current value formed as a result of performing the MAC computation may correspond to data corresponding to the resultant value of performing the MAC computation on the image, audio, image data, and/or target data requiring inference.

According to one embodiment, the transistor array computer 1100 may receive error data for MAC computation from the global buffer 1200. For example, the global buffer 1200 may transmit, to the transistor array computer 1100, data corresponding to a difference value between a target value and a resultant value of performing the MAC computation on the image, audio, image, and/or target data requiring inference. In one example, input gradient data (IGD) that is transferred from the transistor array computer 1100 to the global buffer 1200 may include error data for the MAC computation of the transistor array computer 1100.

According to one embodiment, the weight gradient data (WGD) that is transferred from the global buffer 1200 to the transistor array computer 1100 may correspond to weight gradient data (WGD) that is transferred from the weight gradient computer 1300 to the global buffer 1200.

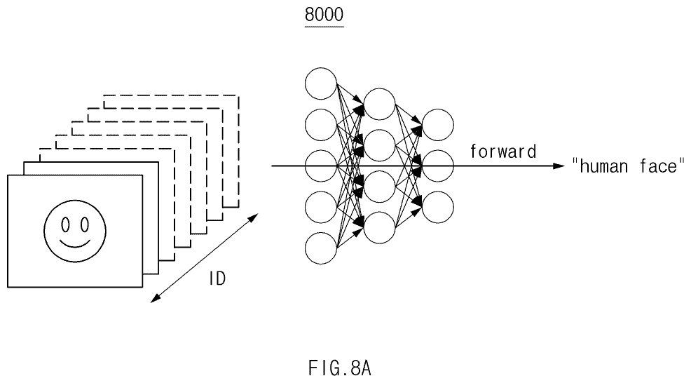

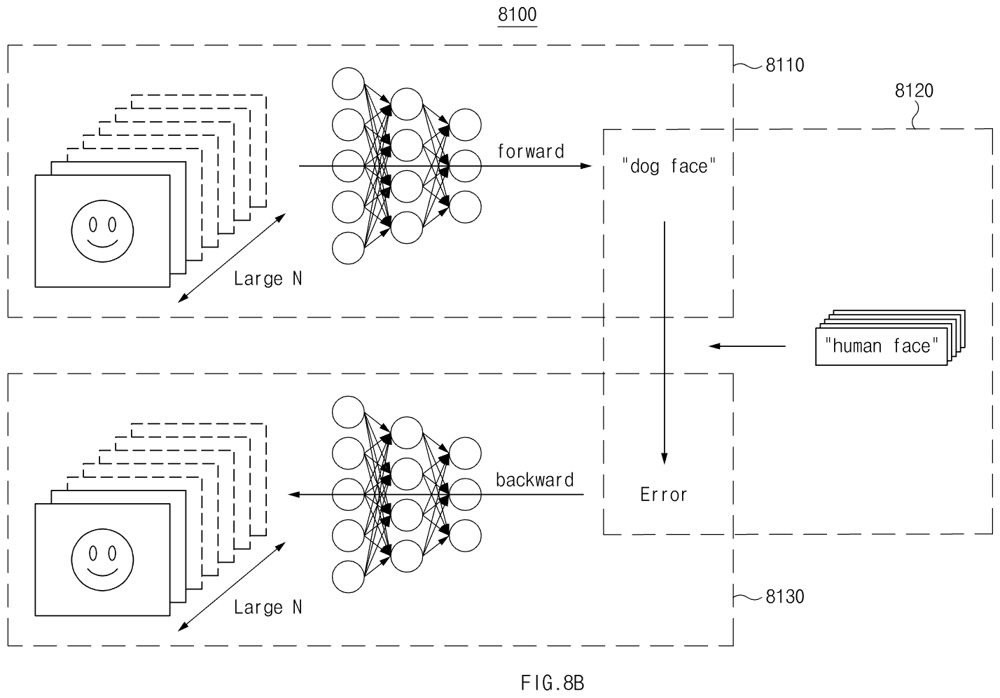

According to one embodiment, the global buffer 1200 may transmit input data (ID) to the transistor array computer 1100. In one example, the global buffer 1200 may receive input gradient data (IGD) from the transistor array computer 1100. In one example, the global buffer 1200 may transmit the weight gradient data (WGD) to the transistor array computer 1100. In one example, the CIM module 1000 may perform inference artificial neural network (ANN) computation based on input data (ID) and/or input gradient data (IGD) that can be transmitted and received (i.e., communicated) between the global buffer 1200 and the transistor array computer 1100. A detailed description of the inference artificial neural network (ANN) computation will be given later with reference to FIG. 8A.

According to one embodiment, the global buffer 1200 may transmit input gradient data (IGD) to the weight gradient computer 1300. In one example, the global buffer 1200 may receive weight gradient data (WGD) from the weight gradient computer 1300. The global buffer 1200 may transmit the weight gradient data (WGD) received from the weight gradient computer 1300 to the transistor array 1100. In one example, the CIM module 1000 may perform a training artificial neural network (ANN) computation based on the input gradient data (IGD) communicated between the global buffer 1200 and the weight gradient computer 1300 and/or the weight gradient data (WGD) transmitted to the transistor array 1100. The training artificial neural network (ANN) computation may correspond to the operation of updating gradient data used in the MAC computation based on the weight gradient data (WGD). A detailed description of the training artificial neural network (ANN) computation will be given later with reference to FIG. 8B.

According to one embodiment, the global buffer 1200 may transmit and receive buffer control data (BCD) to and from the global buffer controller 1400. In one example, the CIM module 1000 may control the storage and transmission of data required for MAC computation, input gradient computation, or weight gradient computation based on buffer control data (BCD) that is communicated between the global buffer 1200 and the global buffer controller 1400. For example, the buffer control data (BCD) may include data indicating the time and/or position at which at least one of the input data (ID), the input gradient data (IGD), and the weight gradient data (WGD) is transmitted or stored.

According to one embodiment, the weight gradient computer 1300 may receive input gradient data (IGD) from the global buffer 1200. In one example, the weight gradient computer 1300 may output weight gradient data (WGD) based on the input gradient data (IGD).

According to one embodiment, the input gradient data (IGD) that is transferred from the global buffer 1200 to the weight gradient computer 1300 may correspond to the input gradient data (IGD) that is transferred from the transistor array computer 1100 to the global buffer 1200. In one example, the input gradient data (IGD) that is transferred from the global buffer 1200 to the weight gradient computer 1300 may include error data for MAC computation of the transistor array computer 1100.

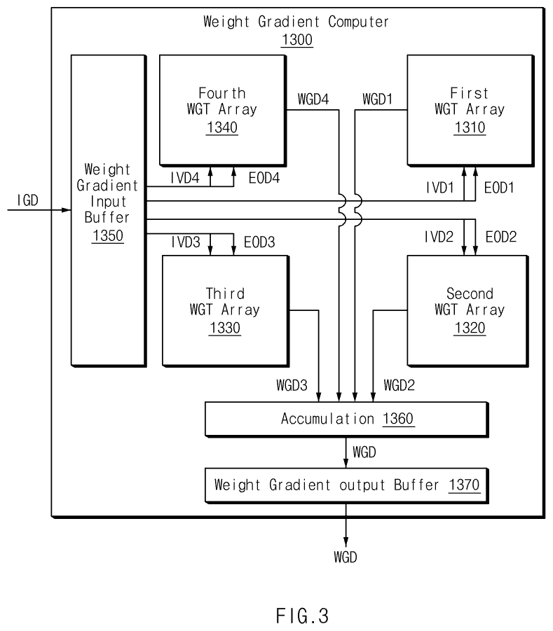

According to one embodiment, the weight gradient data (WGD) that is transferred from the global buffer 1200 to the weight gradient computer 1300 may include data obtained by performing MAC computation on data included in the input gradient data (IGD). For example, the weight gradient data (WGD) may include data corresponding to a resultant value of performing MAC computation on the initial input voltage value and that error data that are included in the input gradient data (IGD). A detailed description of the weight gradient computer 1300 will be given later with reference to FIG. 3.

According to one embodiment, the global buffer controller 1400 may transmit and receive buffer control data (BCD) to and from the global buffer 1200. In one example, the buffer control data (BCD) may include an activation signal, an accumulation signal, or a pooling signal. In one example, the CIM module 1000 may control the storage and transmission of data (e.g., at least one of input data ID, input gradient data IGD, and weight gradient data WGD) required for MAC computation, input gradient computation, or weight gradient computation based on the buffer control data (BCD).

According to one embodiment, based on the activation signal of the buffer control data (BCD), the computation result of a data processing device such as the transistor array computer 1100 and/or the weight gradient computer 1300 may be stored in the global buffer 1200 or may be transmitted to a necessary position.

According to one embodiment, the computation result of a data processing device, such as the transistor array computer 1100 and/or the weight gradient computer 1300, may be accumulated or summed based on an accumulation signal of the buffer control data (BCD).

According to one embodiment, based on a pooling signal of the buffer control data (BCD), during the computation process of a data processing device such as the transistor array computer 1100 and/or the weight gradient computer 1300 used in the CIM module 1000, some processes may be omitted or certain data may be extracted.

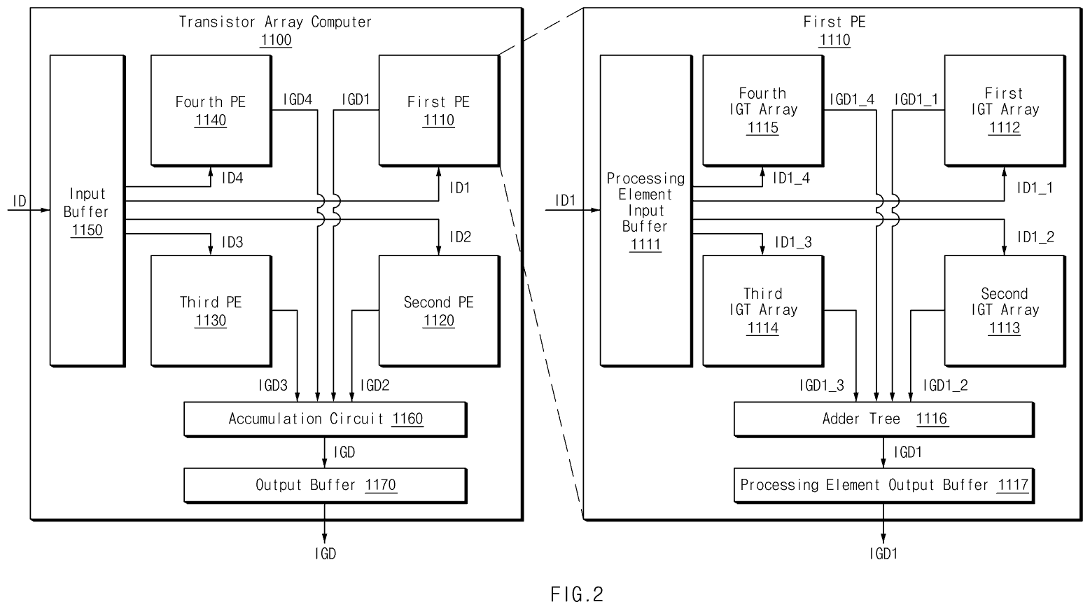

FIG. 2 is a block diagram illustrating an example structure of a transistor array computer according to some embodiments of the present disclosure.

Referring to FIGS. 1 and 2, a transistor array computer 1100 may receive input data (ID), and may output input gradient data (IGD). In one example, the transistor array computer 1100 may include at least one of an input buffer 1150, an accumulation circuit 1160, an output buffer 1170, and first to fourth processing elements (PEs) (1110, 1120, 1130, 1140). Although the present disclosure assumes that the transistor array computer 1100 includes the first to fourth processing elements (1110, 1120, 1130, 1140), the scope or spirit of the present disclosure is not limited thereto, and it should be noted that the number of processing elements in the transistor array computer 1100 is not limited thereto. The configuration of the transistor array computer 1100 according to the present disclosure is only an example, and some components may be added or omitted in the configuration of the transistor array computer 1100. In one embodiment, the transistor array computer 1100 may further include processing elements. In another embodiment, at least some components of the input buffer 1150 or the output buffer 1170 may be included in an external module, such as a global buffer 1200 (see FIG. 1).

According to one embodiment, the first to fourth processing elements (PEs) (1110, 1120, 1130, 1140) may receive first to fourth input data (ID1, ID2, ID3, ID4) respectively from the input buffer 1150, and may output first to fourth input gradient data (IGD1, IGD2, IGD3, IGD4) respectively in response to the received input data. In one example, the first to fourth input data (ID1, ID2, ID3, ID4) may correspond to data included in the input data (ID).

According to one embodiment, the input buffer 1150 may classify input data (ID) according to the positions of the first to fourth processing elements (1110, 1120, 1130, 1140), and may transmit the classified result to the first to fourth processing elements (1110, 1120, 1130, 1140). For example, the first processing element (PE) 1100 (denoted by “first PE” in FIG. 2) may receive the first input data (ID1) from the input buffer 1150.

According to one embodiment, the first to fourth processing elements (PEs) (1110, 1120, 1130, 1140) may generate and output the first to fourth input gradient data (IGD1, IGD2, IGD3, IGD4), respectively. For example, the first processing element (PE) 1110 may transmit the first input gradient data (IGD1) to the accumulation circuit 1160.

According to one embodiment, the accumulation circuit 1160 may receive first to fourth input gradient data (IGD1, IGD2, IGD3, IGD4) from the first to fourth processing elements (PEs) (1110, 1120, 1130, 1140), respectively. In one example, the accumulation circuit 1160 may generate input gradient data (IGD) by summing the received first to fourth input gradient data (IGD1, IGD2, IGD3, IGD4).

According to one embodiment, the output buffer 1170 may store the input gradient data (IGD) received from the accumulation circuit 1160. In one example, the output buffer 1170 may transfer the stored input gradient data (IGD) to the global buffer 1200 (see FIG. 1).

According to one embodiment, a processing element (PE) may include one or more input gradient transistor arrays. In one example, the first processing element (PE) 1110 may include at least one of a processing element (PE) input buffer 1111, first to fourth input gradient transistor arrays (1112, 1113, 1114, 1115), an adder tree 1116, and a processing element (PE) output buffer 1117. Although the present disclosure will be described assuming that the first processing element (PE) 1110 includes the first to fourth input gradient transistor arrays (1112, 1113, 1114, 1115), other implementations are also possible, and it should be noted that the number of input gradient transistor arrays in a first processing element is not limited thereto. The configuration of a processing element (PE) according to the present disclosure is only an example, and some configurations may be added or omitted to or from the processing element (PE). In one embodiment, the processing element (PE) may further include an input gradient transistor array. In another embodiment, at least some configurations of the processing element (PE) input buffer 1111 or the processing element (PE) output buffer 1117 may be included in an external module, for example, the global buffer 1200 (see FIG. 1).

According to one embodiment, the processing element (PE) input buffer 1111 of the first processing element 1110 may transfer the classified first input data ID1 from input buffer 1150 in the form of classified first input data (ID1_1, ID1_2, ID1_3, ID1_4) to the first to fourth input gradient transistor arrays (1112, 1113, 1114, 1115). For example, the first input gradient transistor (IGT) array 1112 of the first processing element (PE) 1110 may receive the 1st_first input data (ID1_1) from the processing element (PE) input buffer 1111.

According to one embodiment, the first to fourth input gradient transistor arrays (1112, 1113, 1114, 1115) of the first processing element (PE) 1110 may receive the classified first input data (ID1_1, ID1_2, ID1_3, or ID1_4) from the processing element (PE) input buffer 1111, and may output the classified first input gradient data (IGD1_1, IGD1_2, IGD1_3, IGD1_4) in response to the received input data. For example, the first input gradient transistor array 1112 of the first processing element (PE) 1110 may receive the 1st_first input data (ID1_1) from the processing element (PE) input buffer 1111, and may transmit the 1st_first input gradient data (IGD1_1) to the adder tree 1116.

According to one embodiment, the adder tree 1116 of the first processing element (PE) 1110 may receive classified first input gradient data (IGD1_1, IGD1_2, IGD1_3, IGD1_4) from the first to fourth input gradient transistor arrays (1112, 1113, 1114, 1115), respectively. In one example, the adder tree 1116 may generate the first input gradient data (IGD1) by summing (or adding) the classified first input gradient data (IGD1_1, IGD1_2, IGD1_3, IGD1_4).

According to one embodiment, the processing element (PE) output buffer 1117 of the first processing element 1110 may store first input gradient data (IGD1) received from the adder tree 1116. In one example, the processing element (PE) output buffer 1117 may transmit the first input gradient data (IGD1) to the accumulation circuit 1160.

Referring to FIGS. 1 and 2, according to one embodiment, the transistor array computer 1100 may correspond to an input gradient computer. The input gradient may correspond to gradients or vectors that are multiplied by a large number of reference data in the machine learning or deep learning algorithm. In one example, the input gradient transistor array of the transistor array computer 1100 may include one transistor and one resistive random access memory (ReRAM) per unit cell. In one example, the transistor array computer 1100 may perform MAC computation on the input data (ID), and may output the input gradient data (IGD) corresponding to the MAC computation.

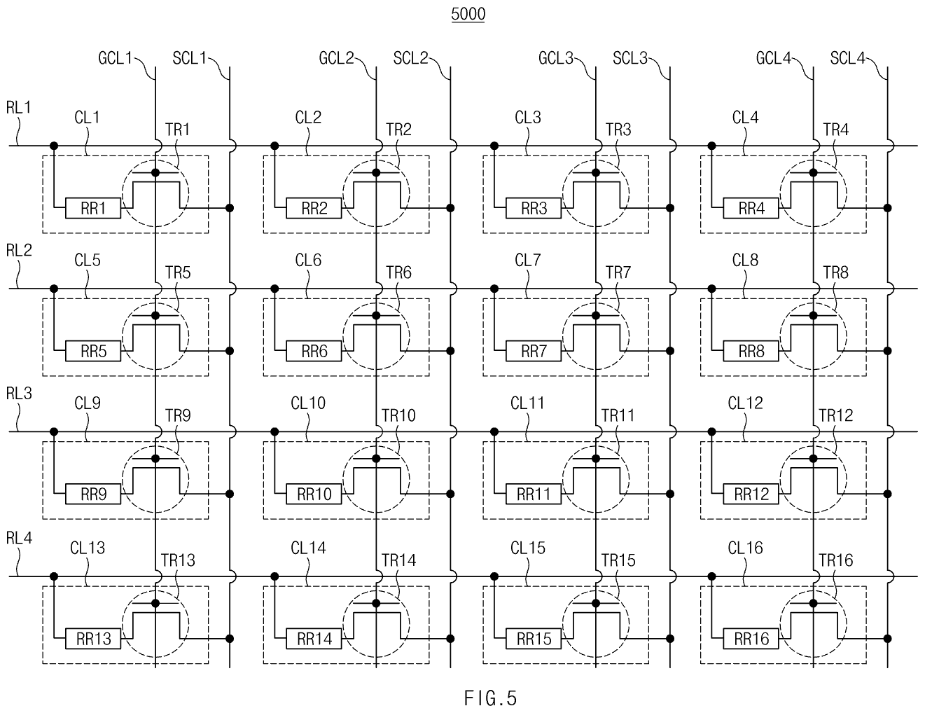

According to one embodiment, MAC computation for preset input gradients and reference data may be performed in a unit cell of the transistor array computer 1100. In one example, input gradients and reference data are input for each unit cell of the transistor array computer 1100, and the operation of multiplying the input gradients and reference data may correspond to an inference artificial neural network (ANN) computation operation. A detailed description of the operation of inputting input gradients and reference data for each unit cell of the transistor array computer 1100 will be given later with reference to FIG. 5.

According to one embodiment, the input gradient data (IGD) may include data that is input to the MAC computation performed by the transistor array computer 1100 and/or data that is output from the MAC computation. For example, referring also to FIG. 1, the transistor array computer 1100 may perform MAC computation for each unit cell. Here, during the MAC computation for each unit cell, a current value is obtained by multiplying an initial input voltage value used in the MAC computation corresponding to image data received from the global buffer 1200 by modifiable weight data (e.g., data corresponding to a conductance value of ReRAM), and the formed current values are summed. Therefore, the input gradient data (IGD) output from the transistor array computer 1100 may include data corresponding to an initial input voltage value and a threshold voltage value that are used in the MAC computation process of the transistor array computer 1100, and/or a current value formed as a result of performing the MAC computation.

According to one embodiment, the input gradient data (IGD) output from the transistor array computer 1100 may include error data for the MAC computation. The error data for the MAC computation may be data corresponding to a difference value between a resultant value of the MAC computation and a target value. The error data for the MAC computation may be calculated by an external module and transmitted to the transistor array computer 1100. In one example, the external module may be an external memory.

According to one embodiment, the input gradient data (IGD) may include data corresponding to an initial input voltage value (dI/dG=V) used for the MAC computation of the transistor array computer 1100. The initial input voltage value used for the MAC computation may correspond to a change amount of a current value formed as a result of performing the MAC computation for a conductance value of the ReRAM. In one example, the input gradient data (IGD) may include data corresponding to the amount of change in error (dE/dI) for the MAC computation for the current value formed as a result of performing the MAC computation.

According to one embodiment, the CIM module 1000 may include one or more transistor array computers 1100, and one or more transistor array computers 1100 may be grouped into one tile. In one example, the CIM module 1000 may include one or more tiles. For example, the CIM module 1000 may be arranged with one or more tiles that transmit and receive data to and from the global buffer 1200.

FIG. 3 is a block diagram illustrating an example structure of a weight gradient computer according to some embodiments of the present disclosure.

Referring to FIG. 3, a weight gradient computer 1300 may receive input gradient data (IGD), and may output weight gradient data (WGD). In one example, the weight gradient computer 1300 may include at least one of a weight gradient input buffer 1350, a weight gradient accumulation circuit 1360, and first to fourth weight gradient transistor arrays (denoted by “WGT arrays”) (1310, 1320, 1330, 1340), and a weight gradient output buffer 1370.

Although it is assumed that the weight gradient computer 1300 includes first to fourth weight gradient transistor arrays (1310, 1320, 1330, 1340) for convenience of description, other implementations are also possible, and it should be noted that the number of weight gradient transistor arrays in a weight gradient computer 1300 is not limited thereto. The configuration of a weight gradient computer 1300 according to the present disclosure is only an example, and some configurations may be added or omitted to or from the weight gradient computer 1300. In one embodiment, the weight gradient computer 1300 may further include a weight gradient transistor array. In another embodiment, at least some configurations of the weight gradient input buffer 1350 or the weight gradient output buffer 1370 may be included in an external module, for example, the global buffer 1200 (see FIG. 1).

According to one embodiment, the input gradient data (IGD) received by the weight gradient input buffer 1350 may include first to fourth initial input voltage value data (IVD1, IVD2, IVD3, IVD4) and/or first to fourth error data (EOD1, EOD2, EOD3, EOD4). In one example, referring to FIG. 1 together, the first to fourth initial input voltage value data (IVD1, IVD2, IVD3, IVD4) may include data corresponding to the initial input voltage value (dI/dG=V) used in the MAC computation of the transistor array computer 1100. In one example, the first to fourth error data (EOD1, EOD2, EOD3, EOD4) may include data corresponding to the amount of change in error (dE/dI) for the MAC computation for the current value formed as a result of performing the MAC computation by the transistor array computer 1100.

According to one embodiment, the weight gradient input buffer 1350 may classify the first to fourth initial input voltage value data (IVD1, IVD2, IVD3, IVD4) according to the positions of the first to fourth weight gradient transistor arrays (1310, 1320, 1330, 1340), and may transmit the classified resultant data to the first to fourth weight gradient transistor arrays (1310, 1320, 1330, 1340), respectively. In addition, the weight gradient input buffer 1350 may classify the first to fourth error data (EOD1, EOD2, EOD3, EOD4) according to the positions of the first to fourth weight gradient transistor arrays (1310, 1320, 1330, 1340), and may transmit the classified resultant data to the first to fourth weight gradient transistor arrays (1310, 1320, 1330, 1340), respectively. For example, the first weight gradient transistor (WGT) array (i.e., first WGT array) 1310 may receive first initial input voltage value data (IVD1) and/or first error data (EOD1) from the weight gradient input buffer 1350.

According to one embodiment, the first to fourth weight gradient transistor arrays (1310, 1320, 1330, 1340) of the weight gradient computer 1300 may receive first to fourth initial input voltage value data (IVD1, IVD2, IVD3, IVD4) from the weight gradient input buffer 1350, respectively. In addition, the first to fourth weight gradient transistor arrays (1310, 1320, 1330, 1340) may receive first to fourth error data (EOD1, EOD2, EOD3, EOD4) from the weight gradient input buffer 1350.

According to one embodiment, the first to fourth weight gradient transistor arrays (1310, 1320, 1330, 1340) may output first to fourth weight gradient data (WGD1, WGD2, WGD3, WGD4), respectively. For example, the first weight gradient transistor array 1310 may receive first initial input voltage value data (IVD1) and first error data (EOD1) from the weight gradient input buffer 1350, and may transmit the first weight gradient data (WGD1) to the accumulation circuit 1360 of the weight gradient computer 1300.

According to one embodiment, the accumulation circuit 1360 of the weight gradient computer 1300 may receive first to fourth weight gradient data (WGD1, WGD2, WGD3, WGD4) from the first to fourth weight gradient transistor arrays (1310, 1320, 1330, 1340). In one example, the accumulation circuit 1360 of the weight gradient computer may generate weight gradient data (WGD) by summing the received first to fourth weight gradient data (WGD1, WGD2, WGD3, WGD4).

According to one embodiment, the weight gradient output buffer 1370 may store the weight gradient data (WGD) received from the accumulation circuit 1360 of the weight gradient computer 1300. In one example, the weight gradient output buffer 1370 may transfer the stored weight gradient data (WGD) to the global buffer 1200 (see FIG. 1).

According to one embodiment, the first to fourth weight gradient transistor arrays (1310, 1320, 1330, 1340) of the weight gradient computer 1300 may include one transistor as a unit cell. In one example, the weight gradient computer 1300 may perform multiplication between the first to fourth error data (EOD1, EOD2, EOD3, EOD4) and the first to fourth initial input voltage value data (IVD1, IVD2, IVD3, IVD4), may perform summation of the multiplication resultant data, and may thus output weight gradient data (WGD).

According to one embodiment, since the weight gradient transistor array includes one transistor as a unit cell, efficiency may increase in terms of cost, energy consumption, and/or an area of the transistor array.

According to one embodiment, the weight gradient transistor array may include one transistor as a unit cell, and when a first voltage is applied to a gate electrode of the transistor included in the unit cell, and a second voltage is applied to a drain electrode of the transistor, a current corresponding to a value obtained by multiplication between the first voltage and the second voltage may flow into the source electrode of the transistor. As a result, multiplication calculation between the first voltage and the second voltage may be performed. In addition, for a transistor array in which the unit transistors are arranged in a plurality of rows and a plurality of columns, currents flowing in the source electrodes of the unit transistors are summed so that a summation calculation (i.e., accumulation calculation) for the multiplication result can be performed.

According to one embodiment, the weight gradient data (WGD) may include data obtained by performing MAC computation on the input gradient data (IGD) of the weight gradient computer 1300. For example, the weight gradient computer 1300 may perform multiplication between the first to fourth initial input voltage value data (IVD1, IVD2, IVD3, IVD4) and the first to fourth error data (EOD1, EOD2, EOD3, EOD4), and may perform accumulation on the multiplication resultant data. Therefore, the weight gradient data (WGD) output from the weight gradient computer 1300 may include data corresponding to the cumulative sum value of the values obtained by multiplying the first to fourth initial input voltage value data (IVD1, IVD2, IVD3, IVD4) by the first to fourth error data (EOD1, EOD2, EOD3, EOD4).

According to one embodiment, the current (Ids) value in a triode mode of the transistor increases in correspondence to the value of ((Vgs−Vth)×(Vds)). Therefore, for the transistors included in the unit cells of the first to fourth weight gradient transistor arrays (1310, 1320, 1330, 1340), if the first to fourth error data (EOD1, EOD2, EOD3, EOD4) each correspond to “(Vgs-Vth)” and the first to fourth initial input voltage value data (IVD1, IVD2, IVD3, IVD4) each correspond to “Vds”, a value obtained by multiplying the first to fourth initial input voltage value data (IVD1, IVD2, IVD3, IVD4) by the first to fourth error data (EOD1, EOD2, EOD3, EOD4), respectively, may correspond to a current value formed in the transistors included in the unit cell. In addition, the sum of the current values formed by the transistors included in each unit cell may correspond to a cumulative sum value for the multiplication result.

For example, for a unit transistor included in a unit cell of the first weight gradient transistor array 1310, if a voltage value corresponding to the first error data (EOD1) is applied to the gate electrode of the unit transistor and a voltage value corresponding to the first initial input voltage value data (IVD1) is applied to the drain electrode of the unit transistor, a current corresponding to a value obtained by multiplying a voltage value corresponding to the first initial input voltage value data (IVD1) by the voltage value corresponding to the first error data (EOD1) may result at the source electrode of the unit transistor. The current value of the current formed at the source electrode of the unit transistor may correspond to the first weight gradient data (WGD1).

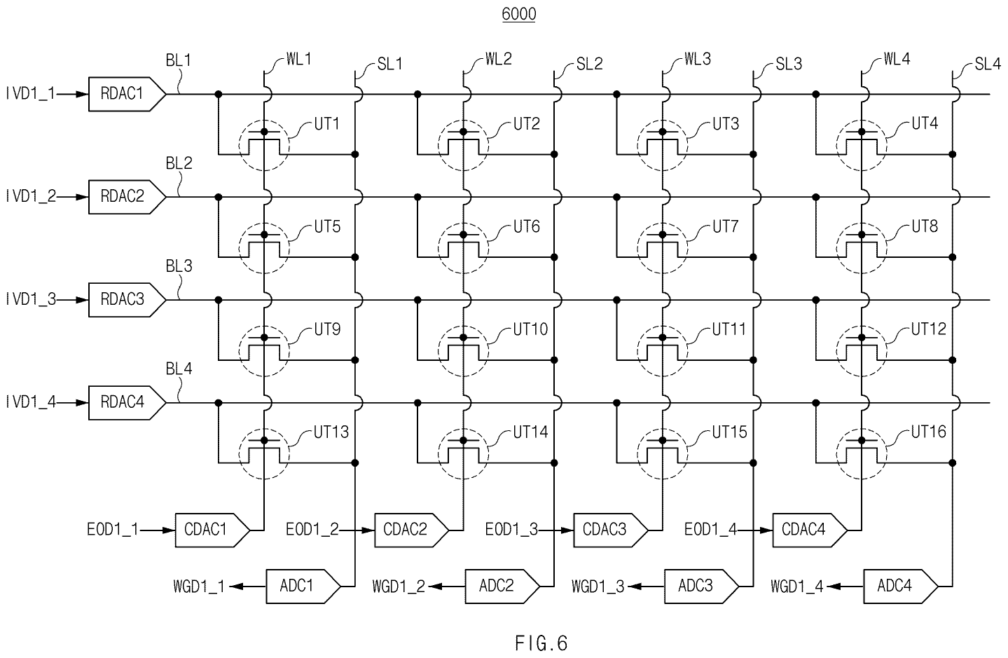

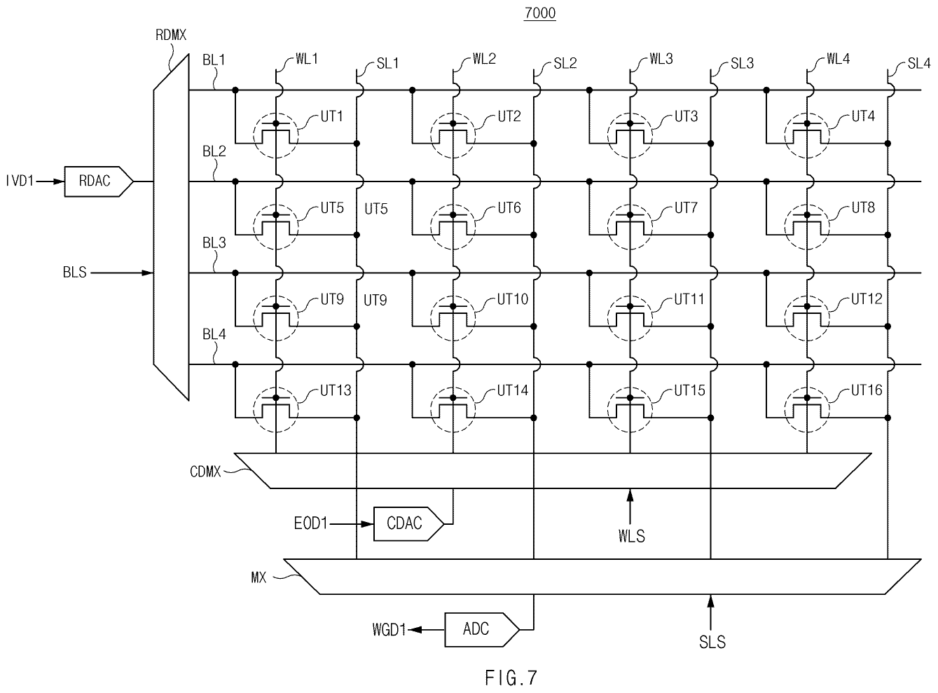

According to one embodiment, the initial input voltage value used in the MAC computation corresponds to “dI/dG=V”, and the amount of change in error for the MAC computation with respect to the current value formed as a result of performing the MAC computation may correspond to “dE/dI”. In addition, a product of the initial input voltage value used in the MAC computation and the amount of change in error for the MAC computation with respect to a current value formed as a result of performing the MAC computation may correspond to “dE/dG”. In one example, “dE/dG” may correspond to a gradient used in the MAC computation with respect to the error for the MAC computation. In one example, since the gradient used in the MAC computation corresponds to “dG”, the gradient used in the MAC computation may be updated by multiplying “dE/dG” by the gradient used in the MAC computation. That is, through correction of the gradient used in the MAC computation, a difference between the resultant value of the MAC computation and the target value may be reduced. A detailed description of the unit transistor of the weight gradient computer 1300 will be given later with reference to FIGS. 6 and 7.

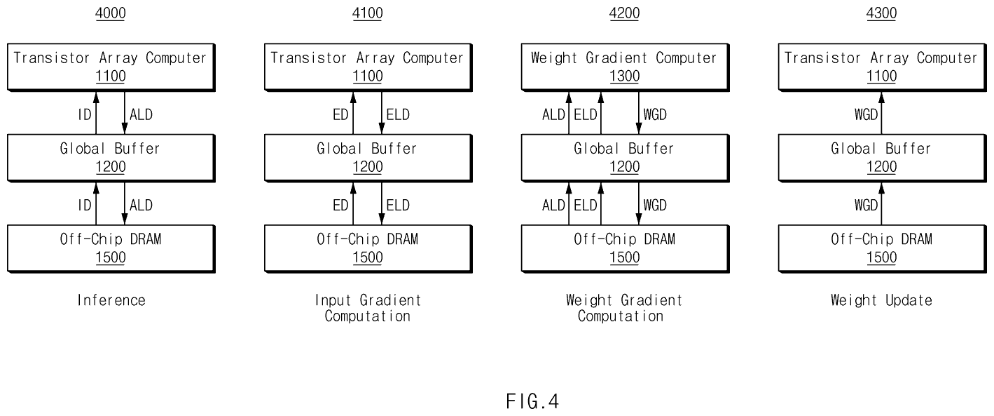

FIG. 4 is a block diagram illustrating example operations of devices for calculating a weight gradient according to some embodiments of the present disclosure.

Referring to FIGS. 1 and 4, a CIM module 1000 may perform an artificial neural network (ANN) training operation not only using the transistor array computer 1100 and the global buffer 1200 that are included in the module, but also using an external memory (e.g., an off-chip DRAM 1500). In one example, the artificial neural network (ANN) may correspond to a multilayer perceptron having multiple hidden layers disposed between one input layer and an output layer. The artificial neural network (ANN) will be described assuming that the ANN corresponds to machine learning or deep learning algorithms described above in FIG. 1. For example, in the description of the artificial neural network (ANN), multiple hidden layers may correspond to gradient data or vectors described above with reference to FIG. 1. In one example, an off-chip DRAM 1500 may correspond to a memory module located outside a CIM module 1000. In the present disclosure, the external memory is described as corresponding to the off-chip DRAM 1500 for convenience of description, but the scope of the present disclosure is not limited thereto, and the external memory is not limited to off-chip DRAMs.

According to one embodiment, the artificial neural network (ANN) training operation performed by the CIM module 1000 may include an inference process 4000, an input gradient computation process 4100, a weight gradient computation process 4200, and/or a weight update process 4300. The artificial neural network (ANN) training operation according to the present disclosure is only an example, and some operations may be added or omitted to or from the AN training operation. For example, the CIM module 1000 may additionally perform a second inference operation based on the gradient updated in the weight update process 4300.

According to one embodiment, the inference process 4000 may be performed based on data transmission/reception (i.e., data communication) between the transistor array computer 1100, the global buffer 1200, and/or the off-chip DRAM 1500. In one example, the off-chip DRAM 1500 may transmit input data (ID) to the global buffer 1200. The global buffer 1200 may transmit input data (ID) received from the off-chip DRAM 1500 to the transistor array computer 1100. The input data (ID) may include images, audio, video data, and/or target data requiring inference. Referring to FIGS. 2 and 4 together, the input data (ID) of FIG. 4 may correspond to the input data (ID) of FIG. 2.

According to one embodiment, the transistor array computer 1100 may perform MAC computation on input data (ID) received from the global buffer 1200, and may generate and output activation data per layer (ALD). In one example, the activation data per layer (ALD) may correspond to data related to the MAC computation of the transistor array computer 1100 for the input data (ID). For example, the activation data per layer (ALD) may include data corresponding to an initial input voltage value (dI/dG=V) used in the MAC computation of the transistor array computer 1100 and/or data corresponding to a current value (I) formed as a result of performing the MAC computation of the transistor array computer 1100. In one example, referring also to FIG. 2, the activation data per layer (ALD) may be included in the input gradient data (IGD) of FIG. 2.

According to one embodiment, the transistor array computer 1100 may transfer the activation data per layer (ALD) to the global buffer 1200. The global buffer 1200 may transmit the activation data per layer (ALD) received from the transistor array computer 1100 to the off-chip DRAM 1500. In one example, the off-chip DRAM 1500 may store the received the activation data per layer (ALD).

According to one embodiment, compared to the input gradient computation process 4100, the weight gradient computation process 4200, and/or the weight update process 4300 (to be described later), the inference process 4000 may correspond to an operation in which generation of the activation data per layer (ALD) is performed in a forward direction based on the input data (ID).

According to one embodiment, the input gradient computation process 4100 may be performed based on data transmission/reception (i.e., data communication) between the transistor array computer 1100, the global buffer 1200, and/or the off-chip DRAM 1500. In one example, the off-chip DRAM 1500 may transmit error data (ED) to the global buffer 1200. The global buffer 1200 may transmit error data (ED) received from the off-chip DRAM 1500 to the transistor array computer 1100. The error data (ED) may include data corresponding to an error identified in the MAC computation process of the transistor array computer 1100. In one example, the error data (ED) may correspond to data based on a difference between preset target data and the resultant data of performing MAC computation.

According to one embodiment, the transistor array computer 1100 may generate error data per layer (ELD) in response to error data (ED) received from the global buffer 1200, and may output the generated ELD. In one example, the error data per layer (ELD) may correspond to data related to MAC computation of the transistor array computer 1100 for the error data (ED). For example, the error data per layer (ELD) may include data corresponding to the amount of change (dE/dI) in error for MAC computation for a current value formed as a result of performing MAC computation of the transistor array computer 1100. In one example, referring also to FIG. 2, the error data per layer (ELD) may be included in the input gradient data (IGD) of FIG. 2.

According to one embodiment, the transistor array computer 1100 may transmit the error data per layer (ELD) to the global buffer 1200. The global buffer 1200 may transmit the error data per layer (ELD) received from the transistor array computer 1100 to the off-chip DRAM 1500. In one example, the off-chip DRAM 1500 may store the received error data per layer (ELD).

According to one embodiment, the input gradient computation process 4100 may correspond to an operation for correcting data related to input data after output data is generated, so that the input gradient computation process 4100 may correspond to an operation for reverse data processing.

According to one embodiment, the input gradient computation process 4100 may include an operation for generating error data for output data. In one example, the input gradient computation process 4100 corresponds to an operation for identifying an input gradient that should be corrected based on error data, and thus may correspond to an operation essential to training of the artificial neural network (ANN).

According to one embodiment, the weight gradient computation process 4200 may be performed based on data transmission/reception (i.e., data communication) between the weight gradient computer 1300, the global buffer 1200, and/or the off-chip DRAM 1500. In one example, the off-chip DRAM 1500 may transmit the activation data per layer (ALD) and/or the error data per layer (ELD) to the global buffer 1200. The global buffer 1200 may transmit the activation data per layer (ALD) and/or the error data per layer (ELD) received from the off-chip DRAM 1500 to the weight gradient computer 1300. In one example, the activation data per layer (ALD) may include data corresponding to an initial input voltage value (dI/dG=V) used in the MAC computation of the transistor array computer 1100. In one example, the error data per layer (ELD) may include data corresponding to the amount of change in error (dE/dI) for the MAC computation with respect to a current value formed as a result of performing the MAC computation of the transistor array computer 1100.

According to one embodiment, the weight gradient computer 1300 may generate weight gradient data (WGD) in response to the activation data per layer (ALD) or the error data per layer (ELD) received from the global buffer 1200, and may output the generated weight gradient data (WGD). In one example, the weight gradient data (WGD) may correspond to data corresponding to a value obtained by multiplying the activation data per layer (ALD) by the error data per layer (ELD). For example, the weight gradient data (WGD) may include a value “(dI/dG)×(dE/dI)=(dE/dG)” obtained by multiplying an initial input voltage value (dI/dG=V) used in the MAC computation of the transistor array computer 1100 by the amount of change in error (dE/dI) for the MAC computation with respect to a current value formed as a result of performing the MAC computation of the transistor array computer 1100.

According to one embodiment, a value “(dI/dG)×(dE/dI)=(dE/dG)” obtained by multiplying (1) an initial input voltage value (dI/dG=V) used in the MAC computation of the transistor array computer 1100 calculated by the weight gradient computer 1300 by (2) the amount of change in error (dE/dI) for the MAC computation with respect to a current value formed as a result of performing the MAC computation of the transistor array computer 1100 may correspond to a value to be calculated by the weight gradient computer 1300 for the operation of the training artificial neural network (ANN) model. For example, since the value “(dE/dG)” may correspond to a value obtained by dividing the change amount of error of the MAC computation by the change amount of the weight or the gradient, the value “(dE/dG)” is applied to the weight or the gradient, resulting in reduction in MAC computation errors. In one example, referring also to FIG. 3, the weight gradient data (WGD) of FIG. 4 may correspond to the weight gradient data (WGD) of FIG. 3.

According to one embodiment, the weight gradient computer 1300 may transmit weight gradient data (WGD) to the global buffer 1200. The global buffer 1200 may transmit the weight gradient data (WGD) received from the weight gradient computer 1300 to the off-chip DRAM 1500. In one example, the off-chip DRAM 1500 may store the received weight gradient data (WGD).

According to one embodiment, the weight gradient computation process 4200 may correspond to an operation for correcting data related to input data after output data is generated, so that the weight gradient computation process 4200 may correspond to the operation for processing data in a reverse direction (i.e., reverse data processing).

According to one embodiment, the weight gradient computation process 4200 may include an operation of calculating a value (dE/dG) obtained by dividing the amount of change in error for the MAC computation of the transistor array computer 1100 by modifiable weight data (e.g., the amount of change in data corresponding to a conductance value of ReRAM). In one example, the weight gradient computation process 4200 may correspond to an operation of identifying a correction value of an input gradient for reducing the error, so that the weight gradient computation process 4200 may correspond to an operation essential to training of the artificial neural network (ANN).

According to one embodiment, the weight update process 4300 may be performed based on data transmission/reception (i.e., data communication) between the transistor array computer 1100, the global buffer 1200, and/or the off-chip DRAM 1500. In one example, the off-chip DRAM 1500 may transmit weight gradient data (WGD) to the global buffer 1200. The global buffer 1200 may transmit weight gradient data (WGD) received from the off-chip DRAM 1500 to the transistor array computer 1100. The weight gradient data (WGD) may include a value “(dI/dG)×(dE/dI)=(dE/dG)” obtained by multiplying the initial input voltage value (dI/dG=V) used in the MAC computation of the transistor array computer 1100 by the amount of change in error (dE/dI) for the MAC computation with respect to a current value formed as a result of performing the MAC computation of the transistor array computer 1100.

According to one embodiment, the transistor array computer 1100 may modify the input gradient value based on the weight gradient data (WGD) received from the global buffer 1200. For example, the transistor array computer 1100 may modify the input gradient value by applying the weight gradient data (WGD) to modifiable weight data (e.g., data corresponding to a conductance value of ReRAM). In one example, based on the modified input gradient value, the transistor array computer 1100 may calculate a resultant value with a relatively smaller error than in the inference process 4000.

According to one embodiment, the weight update process 4300 may correspond to an operation for correcting data related to input data after output data is generated, and thus may correspond to an operation for reverse data processing.

According to one embodiment, the weight update process 4300 may include an operation for correcting a weight or gradient to be applied to input data based on the weight data. In one example, the weight update process 4300 corresponds to an operation for correcting and updating an input gradient that requires correction based on the error, and thus may correspond to an operation essential to training of the artificial neural network (ANN).

FIG. 5 is a diagram illustrating unit cells of a transistor array computer according to some embodiments of the present disclosure.

Referring to FIG. 5, a unit cell array 5000 of the transistor array computer may include first to sixteenth unit cells (CL1˜CL16), first to fourth row lines (RL1˜RL4) connected to drain electrodes of transistors arranged in each row of the unit cell array 5000, first to fourth gate column lines (GCL1˜GCL4) connected to gate electrodes of transistors arranged in each column of the unit cell array 5000, and first to fourth source column lines (SCL1˜SCL4) connected to source electrodes of transistors arranged in each column of the unit cell array 5000.

According to one embodiment, the unit cell may include at least one ReRAM and at least one transistor. For example, a first unit cell (CL1) may include at least one first ReRAM (RR1) and at least one first transistor (TR1). A second unit cell (CL2) may include at least one second ReRAM (RR2) and at least one second transistor (TR2), a third unit cell (CL3) may include at least one third ReRAM (RR3) and at least one third transistor (TR3), a fourth unit cell (CL4) may include at least one fourth ReRAM (RR4) and at least one fourth transistor (TR4), a fifth unit cell (CL5) may include at least one fifth ReRAM (RR5) and at least one fifth transistor (TR5). In the same manner as described above, the sixth to 16^{th} unit cells (CL6˜CL16) may include at least one sixth to 16^{th} ReRAM (RR6˜RR16) and at least one sixth to 16^{th} transistor (TR6˜TR16), respectively.

According to one embodiment, a conductance value of the ReRAM included in a unit cell may correspond to modifiable weight data. In one example, referring also to FIG. 2, a conductance value of the ReRAM included in the unit cell may correspond to gradient data or vectors used in MAC computation to be performed by the transistor array computer 1100. In one example, the operation of multiplying the amount of change in error (dE/dG) for the MAC computation by the gradient used in the MAC computation may correspond to the operation of correcting the weight or gradient.

The configuration of the unit cell array 5000 of the transistor array computer 1100 according to the present disclosure is only an example, and some components may be added or omitted to or from the unit cell array 5000 of the transistor array computer 1100. For example, the unit cell array 5000 of the transistor array computer 1100 may further include a unit cell, a row line, a gate column line, and/or a source column line in addition to the constituent components illustrated in FIG. 5. Although FIG. 5 illustrates a unit cell array formed in a (4×4) matrix structure for convenience of description, FIG. 5 is only an example of a partial configuration of the unit cell array, and the number of unit cells included in the unit cell array 5000 of the transistor array computer is not limited thereto.

According to one embodiment, referring also to FIG. 2, the unit cell array 5000 of the transistor array computer may correspond to the input gradient transistor array of FIG. 2. In FIG. 5, for convenience of description, it is assumed that the unit cell array 5000 of the transistor array computer corresponds to the first input gradient transistor array 1112 of FIG. 2.

According to one embodiment, referring also to FIG. 2, the 1st_first input data (ID1_1) may include data corresponding to first to fourth row voltage values applied to the first to fourth row lines (RL1˜RL4), respectively. For example, the 1st_first input data (ID1_1) may include data corresponding to the first row voltage value applied to the first row line (RL1).

According to one embodiment, referring also to FIG. 2, the 1st_first input data (ID1_1) may include data corresponding to first to fourth gate column voltage values applied to the first to fourth gate column lines (GCL1˜GCL4), respectively. For example, the 1st_first input data (ID1_1) may include data corresponding to the first gate column voltage value applied to the first gate column line (GCL1).

According to one embodiment, referring also to FIG. 2, the 1st_first input gradient data (IGD1_1) may include data corresponding to a current value formed as a result of applying a row voltage and a gate column voltage applied to each of the first to sixteenth unit cells (CL1˜CL16). For example, the 1st_first input gradient data (IGD1_1) may include data corresponding to a current value formed as a result of applying a first row voltage and a first gate column voltage applied to the first unit cell (CL1).

According to one embodiment, a first row voltage may be applied to the first unit cell (CL1) through the first row line (RL1), and a first gate column voltage may be applied through the first gate column line (GCL1). At this time, a current corresponding to a value obtained by multiplying the first row voltage by the first gate column voltage may be formed at the source electrode of the first unit cell (CL1). In addition, a current corresponding to a value obtained by multiplying the first row voltage by the first gate column voltage may be transmitted to the adder tree 1116 of FIG. 2 through the first source column line (SCL1). Likewise, a current corresponding to a value obtained by multiplying the second row voltage by the second gate column voltage may be transmitted to the adder tree 1116 of FIG. 2 through the second source column line (SCL2). In this way, the same concept as described above may also be applied to the second to the sixteenth unit cells (CL2˜CL16).

According to one embodiment, a current value formed at the source electrode of each of the first to sixteenth unit cells (CL1˜CL16) may correspond to a current value formed as a result of performing the MAC computation in the unit cell array 5000 of the transistor array computer. In one example, the 1st_first input gradient data (IGD1_1) may include data related to the MAC computation performed by the first input gradient transistor array 1112 using the first to sixteenth unit cells (CL1˜CL16).

According to one embodiment, data corresponding to a row voltage value included in the 1st_first input data (ID1_1) and data corresponding to a gate column voltage value may correspond to MAC computation input data. In one example, data corresponding to a row voltage value included in the 1st_first input data (ID1_1) may correspond to an initial input voltage value used in MAC computation. In one example, data corresponding to a gate column voltage value included in the 1st_first input data (ID1_1) may correspond to a threshold voltage value used in the MAC computation.

According to one embodiment, data corresponding to a current value included in the 1st_first input gradient data (IGD1_1) may correspond to MAC computation output data. In one example, data corresponding to a current value included in the 1st_first input gradient data (IGD1_1) may correspond to a current value formed as a result of performing MAC computation.

According to one embodiment, the 1st_first input gradient data (IGD1_1) may include data corresponding to a difference value between a current value, formed as a result of applying the first row voltage and the first gate column voltage to the first unit cell (CL1), and a target value. The data corresponding to the difference value between the current value formed as a result of applying the first row voltage and the first gate column voltage to the first unit cell (CL1) and the target value may correspond to error data for MAC computation.

According to one embodiment, the 1st_first input gradient data (IGD1_1) may include data corresponding to the amount of change in error for a current value formed as a result of applying the first row voltage and the first gate column voltage to the first unit cell (CL1). The data corresponding to the amount of change in error for a current value formed as a result of applying the first row voltage and the first gate column voltage to the first unit cell (CL1) may correspond to the amount of change in error for MAC computation for a current value formed as a result of performing MAC computation. That is, the 1st_first input gradient data (IGD1_1) may include data corresponding to the amount of change in error for the MAC computation with respect to a current value formed as a result of performing the MAC computation.

According to one embodiment, the 1st_first input gradient data (IGD1_1) may further include data corresponding to a row voltage value included in the 1st_first input data (ID1_1) and/or data corresponding to a gate column voltage value included in the 1st_first input data (ID1_1). In one example, the row voltage value may correspond to an initial input voltage value used in the MAC computation, and the gate column voltage value may correspond to a threshold voltage value used in the MAC computation. That is, the 1st_first input gradient data (IGD1_1) may include data corresponding to an initial input voltage value used in the MAC computation.

FIGS. 6 and 7 are diagrams illustrating examples of unit transistors of a weight gradient computer according to some embodiments of the present disclosure.

Referring to FIG. 6, a weight gradient transistor array 6000 may include first to sixteenth unit transistors (UT1˜UT16), first to fourth bit-lines (BL1˜BL4) connected to drain electrodes of unit transistors arranged in each row of the weight gradient transistor array 6000, first to fourth word-lines (WL1˜WL4) connected to gate electrodes of unit transistors arranged in each column of the weight gradient transistor array 6000, first to fourth source lines (SL1˜SL4) connected to source electrodes of unit transistors arranged in each column of the weight gradient transistor array 6000, first to fourth row digital analog converters (RDACs) (RDAC1˜RDAC4) for applying a row voltage to the first to fourth bit-lines (BL1˜BL4), first to fourth column digital analog converters (CDACs) (CDAC1˜CDAC4) for applying a column voltage to the first to fourth word-lines (WL1˜WL4), and/or first to fourth analog digital converters (ADCs) (ADC1˜ADC4) for outputting digital signals corresponding to currents flowing in the first to fourth source lines (SL1˜SL4).

The configuration of the weight gradient transistor array 6000 according to the present disclosure is only an example, and some configurations may be added or omitted to or from the weight gradient transistor array 6000. For example, the weight gradient transistor array 6000 may further include unit transistors, bit lines, word lines, source lines, row DACs, column DACs, and/or ADCs in addition to the configuration illustrated in FIG. 6. Although FIG. 6 illustrates a transistor array formed in a (4×4) matrix structure for convenience of description, FIG. 6 is only an example of some configurations of the weight gradient transistor array, and the number of transistors in the weight gradient transistor array 6000 is not limited thereto.

According to one embodiment, and referring also to FIG. 3, the weight gradient transistor array 6000 may correspond to the weight gradient transistor array of FIG. 3. In FIG. 6, for convenience of description, it is assumed that the weight gradient transistor array 6000 corresponds to the first weight gradient transistor array 1310 of FIG. 3.

According to one embodiment, referring also to FIG. 3, the weight gradient input buffer 1350 may classify the first initial input voltage value data (IVD1) received from the input gradient data (IGD). In one example, the weight gradient input buffer 1350 may classify the first initial input voltage value data (IVD1) into the 1st_first initial input voltage value data (IVD1_1), the 2nd_first initial input voltage value data (IVD1_2), the 3rd_first initial input voltage value data (IVD1_3), and the 4th_first initial input voltage value data (IVD1_4) according to columns, rows, and/or coordinates of the weight gradient transistor array 6000. For example, the weight gradient input buffer 1350 may transmit the 1st_first initial input voltage value data (IVD1_1) among the first initial input voltage value data (IVD1) to the first row DAC (RDAC1) corresponding to the first row of the weight gradient transistor array 6000.

According to one embodiment, the 1st_first initial input voltage value data (IVD1_1), the 2nd_first initial input voltage value data (IVD1_2), the 3rd_first initial input voltage value data (IVD1_3), or the 4th_first initial input voltage value data (IVD1_4) may be classified based on a data control signal. For example, the weight gradient input buffer 1350 may control identification information and input timing point of the 1st_first initial input voltage value data (IVD1_1), the 2nd_first initial input voltage value data (IVD1_2), the 3rd_first initial input voltage value data (IVD1_3), or the 4th_first initial input voltage value data (IVD1_4) based on the data control signal. In one example, referring also to FIG. 1, the data control signal may be included in the buffer control data (BCD), and may be transmitted to the weight gradient input buffer 1350 of the weight gradient computer 1300 through the global buffer 1200.

According to one embodiment, referring also to FIG. 3, the weight gradient input buffer 1350 may classify the first error data (EOD1) based on the input gradient data (IGD). In one example, the weight gradient input buffer 1350 may classify the first error data (EOD1) into the 1st_first error data (EOD1_1), the 2nd_first error data (EOD1_2), the 3rd_first error data (EOD1_3), and the 4th_first error data (EOD1_4) according to columns, rows, and/or coordinates of the weight gradient transistor array 6000. For example, the weight gradient input buffer 1350 may transfer the 1st_first error data (EOD1_1) among the first error data (EOD1) to the first column DAC (CDAC1) corresponding to the first column of the weight gradient transistor array 6000.

According to one embodiment, the 1st_first error data (EOD1_1), the 2nd_first error data (EOD1_2), the 3rd_first error data (EOD1_3), or the 4th_first error data (EOD1_4) may be classified based on a data control signal. For example, the weight gradient input buffer 1350 may control identification information and input timing point of the 1st_first error data (EOD1_1), the 2nd_first error data (EOD1_2), the 3rd_first error data (EOD1_3), or the 4th_first error data (EOD1_4) based on the data control signal. In one example, referring also to FIG. 1, the data control signal may be included in the buffer control data (BCD), and may be transmitted to the weight gradient input buffer 1350 of the weight gradient computer 1300 through the global buffer 1200.

According to one embodiment, the weight gradient transistor array 6000 may output classified first weight gradient data (WGD1_1, WGD1_2, WGD1_3, WGD1_4) through the first to fourth ADCs (ADC1˜ADC4) based on classified first initial input voltage value data (IVD1_1, IVD1_2, IVD1_3, IVD1_4) being input to the first to fourth row DACs (RDAC1˜RDAC4) and classified first error data (EOD1_1, EOD1_2, EOD1_3, EOD1_4) being input to the first to fourth column DACs (CDAC1˜ CDAC4). For example, when a voltage corresponding to the 1st_first initial input voltage value data (IVD1_1) is applied to the drain electrode of the first unit transistor (UT1) by the first row DAC (RDAC1), and a voltage corresponding to the 1st_first error data (EOD1_1) is applied to the gate electrode of the first unit transistor (UT1) by the first column DAC (CDAC1), a current corresponding to the 1st_first weight gradient data (WGD1_1) may flow to the source electrode of the first unit transistor (UT1).

According to one embodiment, the first to sixteenth unit transistors (UT1˜UT16) included in the weight gradient transistor array 6000 may correspond to NMOS transistors that output the current through the source electrodes thereof when a row voltage is applied to the drain electrode and a column voltage is applied to the gate electrode.

According to one embodiment, the drain electrodes of the first to fourth unit transistors (UT1˜UT4) arranged in the first row of the weight gradient transistor array 6000 may be connected to the first bit-line (BL1). In one example, referring also to FIG. 5, the first row DAC (RDAC1) may apply a first row voltage to the first bit-line (BL1) so that a first row voltage can be transmitted to the drain electrodes of the first to fourth unit transistors (UT1˜UT4) arranged in the first row. At this time, the first row voltage applied to the first bit-line (BL1) may correspond to the first row voltage applied to the first row line (RL1) of FIG. 5. In one example, the first row voltage may correspond to a voltage corresponding to the 1st_first initial input voltage value data (IVD1_1).

According to one embodiment, the drain electrodes of the fifth to eighth unit transistors (UT5˜UT8) arranged in the second row of the weight gradient transistor array 6000 may be connected to the second bit-line (BL2). In one example, referring also to FIG. 5, the second row DAC (RDAC2) may transmit a second row voltage to the second bit-line (BL2) so that the second row voltage can be transmitted to the drain electrodes of the fifth to eighth unit transistors (UT5˜UT8) arranged in the second row. At this time, the second row voltage applied to the second bit-line (BL2) may correspond to the second row voltage applied to the second row line (RL2) of FIG. 5. In one example, the second row voltage may correspond to a voltage corresponding to the 2nd_first initial input voltage value data (IVD1_2).

According to one embodiment, the ninth to twelfth unit transistors (UT9˜UT12) arranged in the third row of the weight gradient transistor array 6000 or the thirteenth to sixteenth unit transistors (UT13˜UT16) arranged in the fourth row of the weight gradient transistor array 6000 may transmit a row voltage to the drain electrodes thereof in the same manner as the first to fourth unit transistors (UT1˜UT4) arranged in the first row of the weight gradient transistor array 6000 or the fifth to eighth unit transistors (UT5˜UT8) arranged in the second row of the weight gradient transistor array 6000.

According to one embodiment, referring also to FIG. 5, the third row voltage applied to the third bit-line (BL3) may correspond to the third row voltage applied to the third row line (RL3) of FIG. 5. In one example, the third row voltage applied to the third bit-line (BL3) may correspond to a voltage corresponding to the 3rd_first initial input voltage value data (IVD1_3).

According to one embodiment, referring also to FIG. 5, the fourth row voltage applied to the fourth bit-line (BL4) may correspond to the fourth row voltage applied to the fourth row line (RL4) of FIG. 5. In one example, the fourth row voltage applied to the fourth bit-line (BL4) may correspond to a voltage corresponding to the 4th_first initial input voltage value data (IVD1_4).

According to one embodiment, gate electrodes of the first, fifth, ninth, and thirteenth unit transistors (UT1, UT5, UT9, UT13) arranged in the first column of the weight gradient transistor array 6000 may be connected to a first word-line (WL1). In one example, referring also to FIG. 5, the first column DAC (CDAC1) may apply a first column voltage to the first word-line (WL1) to transmit the first column voltage to the gate electrodes of the first, fifth, ninth, and thirteenth unit transistors (UT1, UT5, UT9, UT13) arranged in the first column. At this time, the first column voltage applied to the first word-line (WL1) may correspond to the first gate column voltage applied to the first gate column line (GCL1) of FIG. 5. In one example, the first column voltage may correspond to a voltage corresponding to the 1st_first error data (EOD1_1).

According to one embodiment, the source electrodes of the first, fifth, ninth, and thirteenth unit transistors (UT1, UT5, UT9, UT13) arranged in the first column of the weight gradient transistor array 6000 may be connected to the first source line (SL1). In one example, the first ADC (ADC1) may output a digital signal corresponding to a current flowing into the source electrode of at least one of the first, fifth, ninth, and thirteenth unit transistors (UT1, UT5, UT9, UT13) arranged in the first column through the first source line (SL1). In one example, the first ADC (ADC1) may receive a current flowing into a source electrode of at least one of the first, fifth, ninth, and thirteenth unit transistors (UT1, UT5, UT9, UT13) arranged in the first column. Here, the received current may correspond to a current corresponding to the 1st_first weight gradient data (WGD1_1).

According to one embodiment, the gate electrodes of the second, sixth, tenth, and fourteenth unit transistors (UT2, UT6, UT10, UT14) arranged in the second column of the weight gradient transistor array 6000 may be connected to the second word-line (WL2). In one example, referring also to FIG. 5, the second column DAC (CDAC2) may apply a second column voltage to the second word-line (WL2) to transmit the second column voltage to the gate electrodes of the second, sixth, tenth, and fourteenth unit transistors (UT2, UT6, UT10, UT14) arranged in the second column. At this time, the second column voltage applied to the second word-line (WL2) may correspond to the second gate column voltage applied to the second gate column line (GCL1) of FIG. 5. In one example, the second column voltage may correspond to a voltage corresponding to the 2nd_first error data (EOD1_2).

According to one embodiment, the source electrodes of the second, sixth, tenth, and fourteenth unit transistors (UT2, UT6, UT10, UT14) arranged in the second column of the weight gradient transistor array 6000 may be connected to the second source line (SL2). In one example, the second ADC (ADC2) may output a digital signal corresponding to a current flowing into the source electrode of at least one of the second, sixth, tenth, and fourteenth unit transistors (UT2, UT6, UT10, UT14) arranged in the second column through the second source line (SL2). In one example, the second ADC (ADC2) may receive a current flowing into a source electrode of at least one of the second, sixth, tenth, and fourteenth unit transistors (UT2, UT6, UT10, UT14) arranged in the second column. In this case, the received current may correspond to a current corresponding to the 2nd_first weight gradient data (WGD1_2).

According to one embodiment, the third, seventh, eleventh, and fifteenth unit transistors (UT3, UT7, UT11, UT15) arranged in the third column of the weight gradient transistor array 6000 or the fourth, eighth, twelfth, and sixteenth unit transistors (UT4, UT8, UT12, UT16) arranged in the fourth column of the weight gradient transistor array 6000 may be configured such that each unit transistor can receive a column voltage through a gate electrode thereof in the same manner as in the first, fifth, ninth, and thirteenth unit transistors (UT1, UT5, UT9, UT13) arranged in the first column or as in the second, sixth, tenth, and fourteenth unit transistors (UT2, UT6, UT10, UT14). At this time, referring also to FIG. 5, the third column voltage applied to a third word-line (WL3) may correspond to a third gate column voltage applied to the third gate column line (GCL3) of FIG. 5. In addition, the fourth column voltage applied to a fourth word-line (WL4) may correspond to a fourth gate column voltage applied to the fourth gate column line (GCL4) of FIG. 5. In one example, the third column voltage may correspond to a voltage corresponding to the 3rd_first error data (EOD1_3), and the fourth column voltage may correspond to a voltage corresponding to the 4th_first error data (EOD1_4).

According to one embodiment, the third ADC (ADC3) or the fourth ADC (ADC4) may output a digital signal corresponding to a current flowing into a source electrode of at least one of the third, seventh, eleventh, and fifteenth unit transistors (UT3, UT7, UT11, UT15) arranged in a third column of the weight gradient transistor array 6000 or at least one of the fourth, eighth, twelfth, and sixteenth unit transistors (UT4, UT8, UT12, UT16) arranged in a fourth column, in the same manner as the first ADC (ADC1) or the second ADC (ADC2) described above. In one example, a current flowing into a source electrode of at least one of the third, seventh, eleventh, and fifteenth unit transistors (UT3, UT7, UT11, UT15) arranged in a third column, which is received by the third ADC (ADC3), may correspond to a current corresponding to the 3rd_first weight gradient data (WGD1_3). In one example, a current flowing into a source electrode of at least one of the fourth, eighth, twelfth, and sixteenth unit transistors (UT4, UT8, UT12, UT16) arranged in a fourth column, which is received by a fourth ADC (ADC4), may correspond to a current corresponding to the 4th_first weight gradient data (WGD1_4).

According to one embodiment, referring to FIGS. 2 and 3, the weight gradient input buffer 1350 may transmit the first initial input voltage value data (IVD1) to the weight gradient transistor array 6000. At this time, the first initial input voltage value data (IVD1) may be classified into the 1st_first initial input voltage value data (IVD1_1), the 2nd_first initial input voltage value data (IVD1_2), the 3rd_first initial input voltage value data (IVD1_3), and the 4th_first initial input voltage value data (IVD1_4) according to rows, columns, and/or coordinates of the unit transistors, and the weight gradient input buffer 1350 can transmit the classified resultant data. In one example, the classified first initial voltage value data (IVD1_1, IVD1_2, IVD1_3, IVD1_4) transmitted to the weight gradient transistor array 6000 may include data corresponding to voltage values (dI/dG=V) used in the MAC computation of the transistor array computer 1100.

According to one embodiment, referring to FIGS. 2 and 3 together, the weight gradient input buffer 1350 may transmit the first error data (EOD1) to the weight gradient transistor array 6000. At this time, the first error data (EOD1) may be classified into the 1st_first error data (EOD1_1), the 2nd_first error data (EOD1_2), the 3rd_first error data (EOD1_3), and the 4th_first error data (EOD1_4) according to rows, columns, and/or coordinates of the unit transistors, so that the weight gradient input buffer 1350 can transmit the classified resultant data. In one example, the classified first error data (EOD1_1, EOD1_2, EOD1_3, EOD1_4) transmitted to the weight gradient transistor array 6000 may include data corresponding to the amount of change in error (dE/dI) for the MAC computation for the current value formed as a result of performing the MAC computation of the transistor array computer 1100.

According to one embodiment, the first row DAC (RDAC1) may apply a voltage value corresponding to the initial input voltage value (dI/dG=V) used in MAC computation of the transistor array computer 1100 to the first bit-line based on the 1st_first initial input voltage value data (IVD1_1) received by the weight gradient transistor array 6000. In addition, the first column DAC (CDAC1) may transmit a value corresponding to the amount of change in error (dE/dI) for MAC computation for a current value formed as a result of performing MAC computation of the transistor array computer 1100 to the first word-line based on the 1st_first error data (EOD1_1) received by the weight gradient transistor array 6000.

According to one embodiment, the 1st_first initial input voltage value data (IVD1_1) and the 1st_first error data (EOD1_1) may correspond to a row, a column, and/or coordinates of a unit cell of the transistor array computer 1100 in which the MAC computation has been performed. In one example, referring also to FIG. 2, the 1st_first initial input voltage value data (IVD1_1) may correspond to an initial input voltage value used in the MAC computation that is performed in the first row of the first input gradient transistor array 1112 of the transistor array computer 1100. In one example, referring also to FIG. 2, the 1st_first error data (EOD1_1) may correspond to the amount of change in error for the MAC computation with respect to a current value formed as a result of performing the MAC computation in the first column of the first input gradient transistor array 1112 of the transistor array computer 1100. In the same manner as described above, the initial input voltage value data and the error data may also be applied to the remaining rows other than the first row and the remaining columns other than the first column.

According to one embodiment, a current value flowing into the source electrode of the first unit transistor (UT1) may be calculated as represented by Equation 1 below. In Equation 1, “Ids” may denote a current value flowing into a source electrode in the triode mode of the transistor, “Vgs” may denote a gate input voltage, “Vds” may denote a drain input voltage, “Vth” may denote a threshold voltage, and “A” may denote a constant.

$$Ids = A ( ( Vgs - Vth ) \times Vds - ( ( Vds \hat{} 2 ) / 2 ) ) \qquad [ Equation 1 ]$$

According to one embodiment, referring to FIG. 2 and Equation 1 together, when a voltage value corresponding to “(dI/dG=V)” for the MAC computation of the transistor array computer 1100 is applied to the drain electrode of the first unit transistor (UT1), and a voltage value corresponding to “(dE/dI)” for the MAC computation of the transistor array computer 1100 is applied to the gate electrode of the first unit transistor (UT1), (dE/dI) may correspond to “(Vgs-Vth)”, and “(dI/dG=V)” may correspond to “Vds”. In this case, “Ids” may have a value corresponding to “(dI/dG)*(dE/dI)”, the first unit transistor (UT1) may output a current value corresponding to “(dI/dG)×(dE/dI)=(dE/dG)” through the source electrode of the first unit transistor (UT1).

According to one embodiment, referring also to FIG. 5, the 1st_first initial input voltage value data (IVD1_1) may include data corresponding to an initial input voltage value used in the MAC computation that is performed in the first to fourth cells (CL1˜CL4) arranged in the first row of the unit cell array 5000 of the transistor array computer.

According to one embodiment, referring also to FIG. 5, the 1st_first error data (EOD1_1) may include data corresponding to the amount of change in error for the MAC computation with respect to current values formed as a result of performing the MAC computation of the first, fifth, ninth, and thirteenth cells (CL1, CL5, CL9, CL13) arranged in the first column of the unit cell array 5000 of the transistor array computer.

According to one embodiment, referring also to FIG. 5, data corresponding to the initial input voltage value used in the MAC computation performed in the first unit cell (CL1) may be applied to a drain electrode of the first unit transistor (UT1) of the weight gradient transistor array 6000. In addition, data corresponding to the amount of change in error for the MAC computation with respect to a current value formed as a result of performing the MAC computation performed in the first unit cell (CL1) may be applied to a gate electrode of the first unit transistor (UT1) of the weight gradient transistor array 6000.

According to one embodiment, referring also to FIG. 5, the first row DAC (RDAC1) may apply a voltage corresponding to the initial input voltage value used in the MAC computation of the unit cell array 5000 of the transistor array computer to the first bit-line (BL1). In addition, the first column DAC (CDAC1) may apply a voltage corresponding to the amount of change in error for the MAC computation with respect to a current value formed as a result of performing the MAC computation of the unit cell array 5000 of the transistor array computer to the first word-line (WL1). In this case, a current flowing into the source electrode of the first unit transistor (UT1) may correspond to a value obtained by multiplying the “initial input voltage value used in the MAC computation” by the “amount of change in error for the MAC computation with respect to a current value formed as a result of performing the MAC computation”. In this case, the first ADC (ADC) may generate and output data including a value corresponding to the current flowing into the source electrode of the first unit transistor (UT1) as the 1st_first weight gradient data (WGD1_1).

According to one embodiment, referring also to FIG. 5, the first row DAC (RDAC1) may apply a voltage corresponding to the initial input voltage value used in the MAC computation of the first to fourth unit cells (CL1˜CL4) to the first bit-line (BL1), and the first column DAC (CDAC1) may apply a voltage corresponding to the amount of change in error for the MAC computation with respect to current values formed as a result of performing the MAC computation of the first, fifth, ninth, and thirteenth unit cells (CL1, CL5, CL9, CL13) to the first word-line (WL1). In addition, the second column DAC (CDAC2) may apply a voltage corresponding to the amount of change in error for the MAC computation with respect to current values formed as a result of performing MAC computation of the second, sixth, tenth, and fourteenth unit cells (CL2, CL6, CL10, CL14) to the second word-line (WL2).

According to one embodiment, when the initial input voltage value used in the MAC computation of the first to fourth unit cells (CL1˜CL4) is a first voltage, the amount of change in error for the MAC computation with respect to current values formed as a result of performing the MAC computation of the first, fifth, ninth, and thirteenth unit cells (CL1, CL5, CL9, CL13) is a second voltage, and the amount of change in error for the MAC computation with respect to current values formed as a result of performing the MAC computation of the second, sixth, tenth, and fourteenth unit cells (CL2, CL6, CL10, CL14) is a third voltage. Therefore, when a voltage corresponding to the first voltage is applied to the first bit-line (BL1), a voltage corresponding to the second voltage is applied to the first word-line (WL1), and a voltage corresponding to the third voltage is applied to the second word-line (WL2), the current flowing into the source electrode of the first unit transistor (UT1) may correspond to a value obtained by multiplying the first voltage by the second voltage, and the current flowing into the source electrode of the second unit transistor (UT2) may correspond to a value obtained by multiplying the first voltage by the third voltage. The first ADC (ADC1) may generate data corresponding to a value corresponding to the current flowing into the source electrode of the first unit transistor (UT1) as 1st_first weight gradient data (WGD1_1), and may output the 1st_first weight gradient data (WGD1_1). In addition, the second ADC (ADC2) may generate data corresponding to a value corresponding to the current flowing into the source electrode of the second unit transistor (UT2) as 2nd_first weight gradient data (WGD1_2), and may output the 2nd_first weight gradient data (WGD1_2).

According to one embodiment, operations in which a voltage corresponding to each of the second bit-line (BL2), the first word-line (WL1), and the second word-line (WL2) is applied can also be performed in the same manner as described above. In one example, the weight gradient transistor array 6000 may activate a plurality of word-lines or a plurality of source lines while activating one bit-line at a time.

Referring to FIG. 7, the weight gradient transistor array 7000 may include: first to sixteenth unit transistors (UT1˜UT16); first to fourth bit-lines (BL1˜BL4) connected to drain electrodes of unit transistors arranged in each row of the weight gradient transistor array 7000; first to fourth word-lines (WL1˜WL4) connected to gate electrodes of unit transistors arranged in each column of the weight gradient transistor array 7000; first to fourth source lines (SL1˜SL4) connected to source electrodes of unit transistors arranged in each column of the weight gradient transistor array 7000; a row DAC (RDAC) for applying a row voltage; a bit-line demultiplexer (DEMUX) (i.e., RDMX) that selectively connects at least one of the first to fourth bit-lines (BL1˜BL4) to the row DAC (RDAC); a column DAC (CDAC) for applying a column voltage; a word-line DEMUX (CDMX) that selectively connects at least one of the first to fourth word-lines (WL1˜WL4) to the column DAC (CDAC); an analog-to-digital converter (ADC) that outputs a digital signal corresponding to a current flowing into the first to fourth source lines (SL1˜SL4); and/or a source-line multiplexer (MUX) (i.e., MX) that selectively connects at least one of the first to fourth source lines (SL1˜SL4) to the ADC.

According to one embodiment, referring also to FIG. 6, the weight gradient transistor array 7000 shown in FIG. 7 may further include constituent components that are common to those of the weight gradient transistor array 6000 shown in FIG. 6. In one example, the weight gradient transistor array 7000 shown in FIG. 7 may further include a bit-line DEMUX (RDMX), a word-line DEMUX (CDMX), and/or a source-line MUX (MX) in addition to the configurations of the weight gradient transistor array 6000 of FIG. 6.

According to one embodiment, signals applied to the first to fourth bit-lines (BL1˜BL4), the first to fourth word-lines (WL1˜WL4), and/or the first to fourth source lines (SL1˜SL4) may be controlled with the bit-line DEMUX (RDMX), the word-line DEMUX (CDMX), or the source-line MUX (MX) of the weight gradient transistor array 7000. Among the constituent components shown in FIG. 7, the same constituent elements as those of FIG. 6 have already been described with reference to FIG. 6, and will herein be omitted for brevity.

According to one embodiment, referring also to FIG. 3, the weight gradient transistor array 7000 shown in FIG. 7 may correspond to the weight gradient transistor array shown in FIG. 3. In FIG. 7, for convenience of description, it is assumed that the weight gradient transistor array 7000 of FIG. 7 corresponds to a first weight gradient transistor array 1310 of FIG. 3.

According to one embodiment, referring also to FIG. 3, the weight gradient input buffer 1350 may transmit a first initial input voltage value data (IVD1) to the weight gradient transistor array 7000. In one example, the row DAC (RDAC) may receive the first initial input voltage value data (IVD1). In one example, the row DAC (RDAC) may apply a voltage corresponding to the first initial input voltage value data (IVD1) to at least one of the first to fourth bit-lines (BL1˜BL4). In one example, a bit-line DEMUX (RDMX) may connect the row DAC (RDAC) to at least one of the first to fourth bit-lines (BL1˜BL4) based on a bit-line selection signal (BLS).

According to one embodiment, referring also to FIG. 3, the weight gradient input buffer 1350 may transmit the first error data (EOD1) to the weight gradient transistor array 7000. In one example, the column DAC (CDAC) may receive the first error data (EOD1). In one example, the column DAC (CDAC) may apply a voltage corresponding to the first error data (EOD1) to at least one of the first to fourth word-lines (WL1˜WL4). In one example, the word-line DEMUX (CDMX) may connect the column DAC (CDAC) to at least one of the first to fourth word-lines (WL1˜WL4) based on a word-line selection signal (WLS).

According to one embodiment, the weight gradient transistor array 7000 may output first weight gradient data (WGD1) through the analog-to-digital converter (ADC) based on first initial input voltage value data (IVD1) applied to the row DAC (RDAC) and first error data (EOD1) applied to the column DAC (CDAC). For example, the first bit-line (BL1) and the row DAC (RDAC) are connected to each other by the bit-line DEMUX (RDMX), so that a voltage corresponding to the first initial input voltage value data (IVD1) may be applied to the first bit-line (BL1). In addition, the first word-line (WL1) and the column DAC (CDAC) are connected to each other by the word-line DEMUX (CDMX), so that a voltage corresponding to the first error data (EOD1) may be applied to the first word-line (WL1). In this case, a voltage corresponding to the first initial input voltage value data (IVD1) may be applied to the drain electrode of the first unit transistor (UT1) by the first bit-line (BL1), and a voltage corresponding to the first error data (EOD1) may be applied to the gate electrode of the first unit transistor (UT1) by the first word-line (WL1). At this time, when the first source line (SL1) and the analog-to-digital converter (ADC) are connected to each other by the source-line MUX (MX), the first weight gradient data (WGD1) output from the ADC (ADC) may include data corresponding to a current flowing into the source electrode of the first unit transistor (UT1).

The configuration of the weight gradient transistor array 7000 according to the present disclosure is only an example, and some configurations may be added or omitted to or from the configuration of the weight gradient transistor array 7000. For example, the weight gradient transistor array 7000 may further include unit transistors, bit-lines, word-lines, source lines, row DACs, column DACs, and/or ADCs in addition to the constituent components illustrated in FIG. 7. Although FIG. 7 illustrates a transistor array formed in a (4×4) matrix structure for convenience of description, FIG. 7 is only an example for some configurations of the weight gradient transistor array, and it should be noted that the number of transistors, the number of row DACs, the number of column DACs, and/or the number of ADCs of the weight gradient transistor array 7000 are not limited thereto.

According to one embodiment, in at least at one point in time, a current may simultaneously flow into source electrodes of the first to fourth unit transistors (UT1˜UT4) disposed in the first row of the weight gradient transistor array 7000. In one example, when the first bit-line (BL1) is connected to the row DAC (RDAC) by the bit-line DEMUX (RDMX), the row DAC (RDAC) may apply a voltage corresponding to the first initial input voltage value data (IVD1) to the first bit-line (BL1). In addition, in at least at one point in time, the word-line DEMUX (CDMX), the column DAC (CDAC) may apply a voltage corresponding to the first error data (EOD1) to at least one connected word-line when at least one of the first to fourth word-lines (WL1˜WL4) is connected to the column DAC (CDAC). As a result, when at least one of the first to fourth source lines (SL1˜SL4) is connected to the analog-to-digital converter (ADC) by a source-line MUX (MX), the ADC may generate and output data corresponding to the sum of currents flowing into source electrodes of unit transistors through the connected source lines as first weight gradient data (WGD1).

According to one embodiment, referring also to FIG. 2, when the first bit-line (BL1) is connected to the row DAC (RDAC) by the bit-line DEMUX (RDMX), the row DAC (RDAC) may transmit, to the first bit-line (BL1), a voltage corresponding to the first voltage (dI/dG) serving as the initial input voltage value used in the MAC computation of the transistor array computer 1100. In addition, when at least one of the first to fourth word-lines (WL1˜WL4) is simultaneously connected to the column DAC (CDAC) by the word-line DEMUX (CDMX) simultaneously at least at one point in time, the column DAC (CDAC) may simultaneously transmit a voltage corresponding to a second voltage “(dE/dI)” corresponding to the amount of change in error for the MAC computation with respect to a current value formed as a result of performing the MAC computation of the transistor array computer 1100, to at least one connected word-line at least at one point in time. At this time, the current flowing into the source electrode of each of the unit transistors (UT1˜UT4) connected to the first bit-line may correspond to a value obtained by multiplying the first voltage “(dI/dG)” by the second voltage “(dI/dG)×(dE/dI)=(dE/dG)”. In this case, when at least one of the first to fourth source lines (SL1˜SL4) is connected to the ADC by the source-line MUX (MX), the ADC may generate and output data corresponding to the sum “(4×(dE/dG))” of the currents flowing into the source electrodes of the unit transistors as the first weight gradient data (WGD1) through the connected source line.

According to one embodiment, similar to the above-described method, the weight gradient transistor array 7000 may sequentially generate and output data corresponding to the sum of currents flowing into the source electrodes of the unit transistors (UT5˜UT8) disposed in the second row of the weight gradient transistor array 7000, the sum of currents flowing into the source electrodes of the unit transistors (UT9˜UT12) disposed in the third row of the weight gradient transistor array 7000, or the sum of currents flowing into the source electrodes of the unit transistors (UT13˜UT16) disposed in the fourth row of the weight gradient transistor array 7000.

FIG. 8A is a diagram illustrating an example of an inference artificial neural network (ANN) model according to some embodiments of the present disclosure.

Referring to FIG. 8A, an inference artificial neural network (ANN) computation process 8000 may include a process of calculating a weight from input data and deriving a resultant value based on the result of calculation. For example, if the input data is image data regarding a face, the inference artificial neural network (ANN) computation process 8000 may include a process for identifying a human face among the input data and deriving a result called “human face” based on the identification result. In one example, MAC computation may be performed in the process of multiplying the input data by a weight or a gradient. According to one embodiment, the input gradient may correspond to a gradient multiplied by the input data to derive the result of MAC computation.

According to one embodiment, when applying preset weights or gradients to input data, the output value changes depending on the weights or gradients, so that the weights or gradients may need to be modified depending on the output value. In one example, in order to derive a desired result for the input data, the process of multiplying or modifying the weights or gradients in the forward propagation direction from the input data by or to the resultant value may correspond to the inference artificial neural network (ANN) computation process 8000.

According to one embodiment, referring also to FIG. 4, the inference process 4000 may correspond to the inference artificial neural network (ANN) computation process 8000. In one example, the inference artificial neural network (ANN) computation process 8000 may include a process of performing data communication (i.e., data transmission/reception) between the transistor array computer 1100, the global buffer 1200, or an external memory (e.g., off-chip DRAM 1500). For example, image data regarding the face may correspond to the input data (ID).

FIG. 8B is a diagram illustrating an example of a training artificial neural network (ANN) model according to some embodiments of the present disclosure.

Referring to FIG. 8B, a training artificial neural network (ANN) computation process 8100 may include an inference process 8110, an error checking process 8120, and/or an update process 8130. In one example, referring also to FIG. 8A, the inference process may correspond to the inference artificial neural network (ANN) computation process 8000 of FIG. 8A.

According to one embodiment, the inference process 8110 may include a process of calculating a weight from input data and deriving a resultant value. For example, when the input data is image data about a face, the inference process 8100 may include a process for identifying a human face among the input data and deriving a result called “human face”. For example, the inference process 8110 may derive a result called “dog face” as a result of applying a weight or gradient to the input data, even though the input data is image data about a human face.

According to one embodiment, the error checking process 8120 may include a process of determining a difference between a target value and the resultant value derived from the weight calculated based on the input data. For example, the error checking process 8120 may check a difference value between the resultant value “dog face” derived from the result of calculating the weight or gradient based on the input data and a target result “human face”. For example, in the error checking process 8120, error data may be generated based on the MAC computation input data and/or the MAC computation output data of each transistor that has been used to the resultant data “dog face” and “human face”.

According to one embodiment, referring also to FIG. 4, the input gradient computation process 4100 or the weight gradient computation process 4200 may correspond to the error checking process 8120. In one example, the training artificial neural network computation process 8100 may include a process of performing data communication (data transmission/reception) between the transistor array computer 1100, the global buffer 1200, the weight gradient computer 1300, or an external memory (e.g., the off-chip DRAM 1500). For example, data about errors of “dog face” and “human face” may correspond to error data (ED). In addition, a correction value for correcting a gradient or weight based on an error may correspond to weight gradient data (WGD).

According to one embodiment, the update process 8130 may include a process of confirming an error value according to an output value in order to modify a gradient or weight, and correcting the gradient or weight in a reverse order from the output-to-input direction based on the confirmed error value. In one example, the gradient or error used in the inference process 8100 may be corrected based on a correction value for correcting the gradient or weight based on the error identified in the error checking process 8120. In one example, the process of correcting the gradient or weight through back propagation (i.e., in a direction from the result data to the input data) based on the error value obtained after completion the inference process 8100 may correspond to the update process 8130.

According to one embodiment, referring also to FIG. 4, the weight update process 4300 may correspond to the update process 8130. In one example, the update process 8130 may include a process of performing data communication (data transmission/reception) between the transistor array computer 1100, the global buffer 1200, and/or an external memory (e.g., the off-chip DRAM 1500). For example, a correction value for correcting the gradient or weight based on the error may correspond to weight gradient data (WGD). In one example, based on the weight gradient data (WGD), the gradient or weight may be corrected through back propagation.

According to one embodiment, the training artificial neural network (ANN) computation process 8100 may perform the artificial neural network (ANN) computation based on the large amount of input data. In one example, the training artificial neural network (ANN) computation process 8100 may include a process of performing MAC computation of the gradient or weight for the large amount of input data, and then performing MAC computation in the backward direction for the derived error. In one example, the CIM module 1000 of FIG. 1 can improve the efficiency of the area and power consumption of a transistor array that performs MAC computation for the large amount of input data, and thus can improve the efficiency of training artificial neural network (ANN) computation.

As is apparent from the above description, the Compute In Memory (CIM) module according to the embodiments of the present disclosure may increase the efficiency of an area and power consumption of the transistor array for use in the weight gradient computer included in the CIM module.

The embodiments of the present disclosure may provide a variety of effects capable of being directly or indirectly recognized through the above-mentioned patent document.

Those skilled in the art will appreciate that the present disclosure may be carried out in other specific ways than those set forth herein. In addition, claims that are not explicitly presented in the appended claims may be presented in combination as an embodiment or included as a new claim by a subsequent amendment after the application is filed.

Although a number of illustrative embodiments have been described, it should be understood that modifications and enhancements to the disclosed embodiments and other embodiments can be devised based on what is described and/or illustrated in this patent document.

What is claimed is:

1. A Compute In Memory (CIM) module comprising:
a transistor array computer including at least one transistor and at least one resistive random access memory (ReRAM) for each unit cell;
a buffer; and
a weight gradient computer including at least one unit transistor,
wherein the weight gradient computer includes:
a row digital-to-analog converter (DAC) configured to apply a voltage corresponding to an initial input voltage value (dI/dG=V) used in multiplication and accumulation (MAC) computation to a first electrode of the unit transistor;
a column digital-to-analog converter (DAC) configured to apply a voltage corresponding to a change amount in error (dE/dI) for the MAC computation with respect to a current value formed as a result of performing the MAC computation to a second electrode of the unit transistor; and
an analog-to-digital converter (ADC) configured to output a digital signal corresponding to a current flowing into a third electrode of the unit transistor.

2. The CIM module according to claim 1, wherein the transistor array computer is configured to:
generate MAC computation input data and MAC computation output data in response to the MAC computation.

3. The CIM module according to claim 2, wherein the MAC computation input data includes:
at least one of data corresponding to an initial input voltage value used in the MAC computation and data corresponding to a threshold voltage value.

4. The CIM module according to claim 2, wherein the buffer is configured to:
receive the MAC computation output data and the MAC computation input data from the transistor array computer; and
transmit the received MAC computation output data and the received MAC computation input data to the row DAC or the column DAC.

5. The CIM module according to claim 2, wherein the MAC computation output data includes:
at least one of error data for the MAC computation and data corresponding to a current value formed as a result of performing the MAC computation.

6. The CIM module according to claim 1, wherein:
the first electrode corresponds to a drain electrode of the unit transistor;
the second electrode corresponds to a gate electrode of the unit transistor; and
the third electrode corresponds to a source electrode of the unit transistor.

7. The CIM module according to claim 1, wherein the buffer is configured to:
receive data corresponding to the current flowing from the ADC toward the third electrode.

8. The CIM module according to claim 7, wherein the buffer is configured to:
transmit data corresponding to the current flowing into the third electrode to the transistor array computer.

9. A Compute In Memory (CIM) module comprising:
a first transistor array in which a plurality of unit transistors is arranged; and
a second transistor array configured to perform multiplication and accumulation (MAC) computation,
wherein the first transistor array includes:
a first row digital-to-analog converter (DAC) configured to apply a voltage corresponding to a first initial input voltage value used in the MAC computation to drain electrodes of the unit transistors arranged in a first row of the first transistor array;
a first column DAC configured to apply a voltage corresponding to a change amount of a first error for the MAC computation with respect to a first current value formed as a result of performing the MAC computation to gate electrodes of the unit transistors arranged in a first column of the first transistor array; and
a first analog-to-digital converter (ADC) configured to output a digital signal corresponding to a current flowing into source electrodes of the unit transistors arranged in the first column.

10. The Compute In Memory (CIM) module according to claim 9, wherein the first transistor array further includes:
a second row DAC configured to apply a voltage corresponding to a second initial input voltage value used in the MAC computation to drain electrodes of the unit transistors arranged in a second row of the first transistor array.

11. The Compute In Memory (CIM) module according to claim 9, wherein the first transistor array includes:
a second column DAC configured to transmit, to gate electrodes of the unit transistors arranged in a second column of the first transistor array, a voltage corresponding to a change amount of a second error for the MAC computation with respect to a second current value formed as a result of performing the MAC computation; and
a second ADC configured to output a digital signal corresponding to a current flowing into source electrodes of the unit transistors arranged in the second column.

12. The Compute In Memory (CIM) module according to claim 11, wherein:
a voltage corresponding to a change amount of a first error for the MAC computation with respect to a first current value formed as a result of performing the MAC computation, and a voltage corresponding to a change amount of a second error for the MAC computation with respect to a second current value formed as a result of performing the MAC computation, are applied simultaneously at least at one point in time.

13. The Compute In Memory (CIM) module according to claim 11, wherein the first ADC and the second ADC are configured to:
simultaneously output a digital signal corresponding to a current at least at one point in time.

14. The Compute In Memory (CIM) module according to claim 9, further comprising:
a buffer configured to receive, from the second transistor array, data corresponding to a first initial input voltage value used in the MAC computation and data corresponding to a change amount of a first error for the MAC computation with respect to a first current value formed as a result of performing the MAC computation.

15. A Compute In Memory (CIM) module comprising:
a transistor array computer including at least one transistor and at least one resistive random access memory (ReRAM) for each unit cell;
a buffer; and
a weight gradient computer in which unit transistors are arranged in a plurality of rows and a plurality of columns,
wherein the weight gradient computer includes:
a plurality of bit-lines configured to transmit a signal corresponding to an initial input voltage value used in multiplication and accumulation (MAC) computation to first electrodes of unit transistors arranged in each row;
a plurality of word-lines configured to transmit, to second electrodes of unit transistors arranged in each column, a signal corresponding to a change amount in error for the MAC computation with respect to a current value formed as a result of performing the MAC computation; and
a plurality of source lines configured to transmit a signal corresponding to a current flowing into third electrodes of unit transistors arranged in each column.

16. The Compute In Memory (CIM) module according to claim 15, further comprising:
a row digital-to-analog converter (DAC) configured to generate a signal corresponding to the initial input voltage value; and
a bit-line demultiplexer (DEMUX) configured to selectively connect at least one of the plurality of bit-lines to the row DAC.

17. The Compute In Memory (CIM) module according to claim 15, further comprising:
a column DAC configured to generate a signal corresponding to a change amount of an error for the MAC computation with respect to a current value formed as a result of performing the MAC computation; and
a word-line demultiplexer (DEMUX) configured to selectively connect at least one of the plurality of word-lines to the column DAC.

18. The Compute In Memory (CIM) module according to claim 15, further comprising:
an analog-to-digital converter (ADC); and
a source-line multiplexer (MUX) configured to selectively connect at least one of the plurality of source lines to the ADC.

19. The Compute In Memory (CIM) module according to claim 15, wherein:
each of the first electrodes corresponds to each of drain electrodes of the unit transistors;
each of the second electrodes corresponds to each of gate electrodes of the unit transistors; and
each of the third electrodes corresponds to each of source electrodes of the unit transistors.

20. The Compute In Memory (CIM) module according to claim 19, wherein the buffer is configured to:
store data corresponding to a current flowing into source electrodes of the unit transistors.
